(19) United States
(12) Patent Application Publication
(10) Pub. No.: US 2007/0055410 A1
(43) Pub. Date: Mar. 8, 2007

(54) Control device, control method, and computer product

(76) Inventor: Hiroshi Morohoshi, Kanagawa (JP)

Correspondence Address: HARNESS, DICKEY & PIERCE, P.L.C., P.O. BOX 8910, RESTON, VA, 20195, US

(21) Appl. No.: 11/498,057

(22) Filed: Aug. 3, 2006

(30) Foreign Application Priority Data
Aug. 12, 2005 (JP) 2005-234916
Mar. 15, 2006 (JP) 2006-071287

(51) Int. Cl. G05B 13/02; H03K 19/177; G06F 17/00; H01L 25/00; G05B 11/32; G05D 1/02; G05D 1/10

(52) U.S. Cl. 700/302; 326/41; 700/28; 700/69; 700/94

(57) ABSTRACT

An input device includes an accepting unit that is made of a soft material having at least one of a concave form and a convex form and accepts an input from a user, a detecting unit that detects the operating force, and a control unit that determines an operation to be performed based on the operating force.

### CROSS-REFERENCE TO RELATED APPLICATIONS

The present document incorporates by reference the entire contents of Japanese priority document, 2005-234916 filed in Japan on Aug. 12, 2005 and 2006-071287 filed in Japan on Mar. 15, 2006.

### BACKGROUND OF THE INVENTION

1. Field of the Invention

The present invention generally relates to a technology for controlling an input from a user, and specifically to sensing pressure force applied by the user in one of two directions.

2. Description of the Related Art

Japanese Patent Laid-Open No. H8-271285 discloses a typical technology of electronically controlling sound volume and the like by detecting an amount of rotation, i.e., rotating angle, of a knob. The rotating angle can be detected by counting the number of on/off operations performed by a sliding contact point crossing a printed electrode in the knob. The technology also includes detecting the rotating direction of the knob by monitoring signals from one of two contact points with which a leaf switch contacts. The leaf switch functions as a rotation-direction switch with help of a connector.

However, it is difficult to distinguish a start point and an end point of a rotating body when the user inputs the information intermittently, there is a problem that fine control is difficult. There is another problem that the contact point wears due to the sliding action on the electrode.

### SUMMARY OF THE INVENTION

It is an object of the present invention to at least partially solve the problems in the conventional technology.

According to an aspect of the present invention, a control device includes an accepting unit that is made of a soft material having at least one of a concave form and a convex form and accepts an input from a user by receiving operating force from the user; a detecting unit that detects the operating force received by the accepting unit; and a control unit that determines an operation to be performed based on the operating force detected by the detecting unit.

According to another aspect of the present invention, a control device includes an accepting unit that is made of a soft material and accepts an input from a user by receiving operating force from the user; a detecting unit that detects the operating force received by the accepting unit; a delivering unit that reduces the operating force received by the accepting unit and delivers the operating force to the detecting unit; and a control unit that determines an operation to be performed based on the operating force detected by the detecting unit.

According to still another aspect of the present invention, a controlling method includes accepting an input from a user by receiving operating force from an accepting unit that is made of a soft material having at least one of a concave form and a convex form; detecting the operating force received by the accepting unit using a detecting unit; and determining an operation to be performed based on the operating force detected by the detecting unit.

According to still another aspect of the present invention, a computer program product comprising a computer usable medium having computer readable program codes embodied in the medium that when executed causes a computer to execute determining an operation of displaying data based on at least one of a level of operating force received by an accepting unit that is made of a soft material having at least one of a concave form and a convex form, a duration time of the operating force, and a speed of the operating force; and displaying the data based on the operation determined at the determining.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic for explaining an electronic paper using a control device that includes an input device according to a first embodiment of the present invention;

FIG. 2 is a side view of the input device shown in FIG. 1;

FIG. 3 is an enlarged perspective view for explaining a form of an input member shown in FIG. 1;

FIG. 4 is a cross section of the input device;

FIG. 5 is a schematic for explaining an input action performed by a user;

FIG. 6 is another schematic for explaining an input action performed by the user;

FIG. 7 is a block diagram of the control device shown in FIG. 1;

FIG. 8 is a flowchart of a procedure for switching contents of data to be displayed using the control device;

FIG. 9 is a schematic for explaining how the control device determines switched page amount;

FIG. 10A is a schematic for explaining a case of determining the switched page amount based on pressing speed and pressing time;

FIG. 10B is a schematic for explaining a case of determining the switched page amount based on the pressure force and the pressing time;

FIG. 10C is a schematic for explaining a case of determining the switched page amount based on the pressing speed and the pressure force;

FIG. 11 is a cross section of an input device according to a second embodiment of the present invention;

FIG. 12 is a cross section of an input device according to a third embodiment of the present invention;

FIG. 13 is a cross section of an input device according to a fourth embodiment of the present invention;

FIG. 14 is a cross section of an input device according to a fifth embodiment of the present invention;

FIG. 15 is a cross section of an input device according to a sixth embodiment of the present invention;

FIG. 16 is a cross section of an input device according to a seventh embodiment of the present invention;

FIG. 17 is a cross section of an input device according to an eighth embodiment of the present invention;

FIG. 18 is a cross section of an input device according to a ninth embodiment of the present invention;

FIG. 19 is a cross section of an input device according to a tenth embodiment of the present invention;

FIG. 20 is a cross section of an input device according to an eleventh embodiment of the present invention;

FIG. 21 is a cross section of an input device according to a twelfth embodiment of the present invention;

FIG. 22 is a cross section of an input device according to a thirteenth embodiment of the present invention;

FIG. 23 is a cross section of an input device according to a fourteenth embodiment of the present invention;

FIG. 24A is a cross section of a buffer material shown in FIG. 23;

FIG. 24B is a top view of the buffer material shown in FIG. 24A;

FIG. 25A is a cross section of a buffer material according to a fifteenth embodiment of the present invention;

FIG. 25B is a top view of the buffer material shown in FIG. 25A;

FIG. 26 is a cross section of an input device according to a sixteenth embodiment of the present invention; and

FIG. 27 is an example of the control device according to any one of the first to sixteenth embodiments installed in a personal digital assistant.

### DETAILED DESCRIPTION OF THE PREFERRED EMBODIMENTS

Exemplary embodiments of the present invention are explained below in detail referring to the accompanying drawings. While an input device according to the embodiments is installed in a control device that holds an electronic paper to display data thereon, the present invention is not limited to the embodiments explained below.

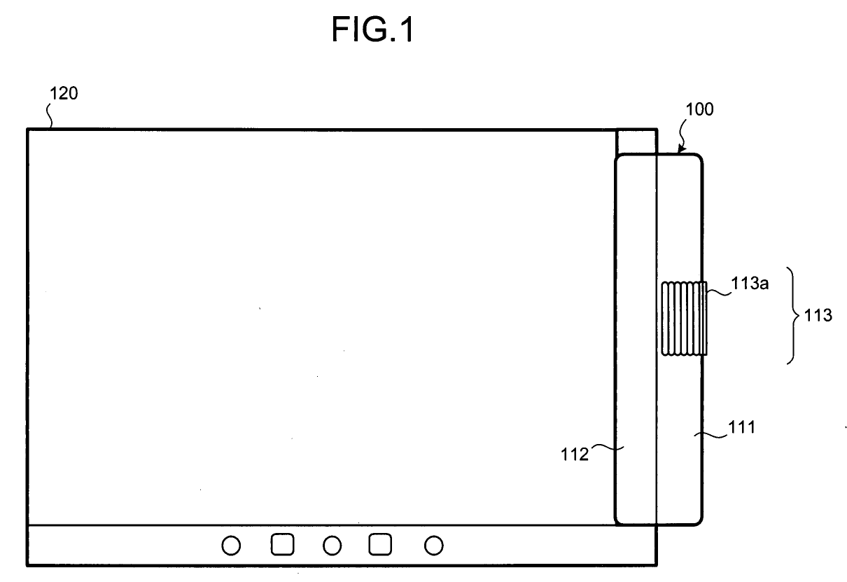

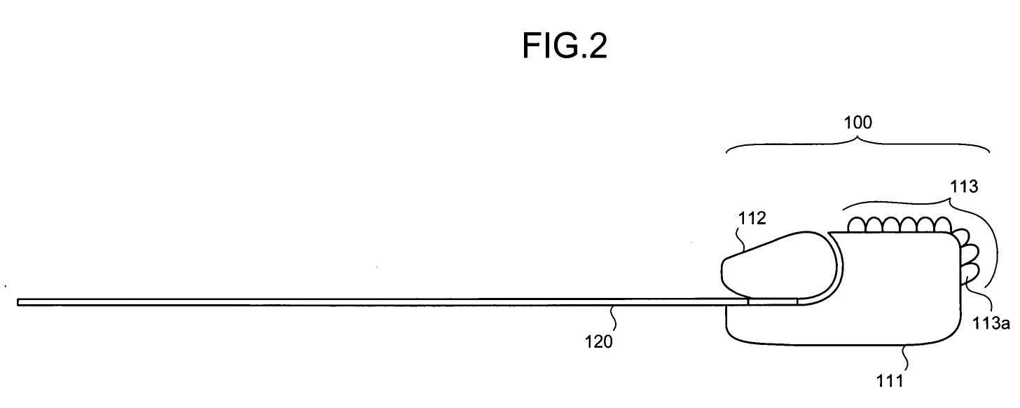

FIG. 1 is a schematic for explaining the electronic paper using the control device that includes the input device according to a first embodiment of the present invention. FIG. 2 is a side view of the input device shown in FIG. 1.

According to the first embodiment, a control device 100 is installed in an electronic paper 120. The electronic paper 120 is an electrically rewritable and portable electronic display that is very thin and light like a sheet of paper. The control device 100 performs controls such as switching contents of data displayed on the electronic paper 120 based on inputs from a user. The control device 100 includes a control device body 111, an attachment unit 112, and an input device 113.

The attachment unit 112 attaches the electronic paper 120 to the control device 100. As shown in FIG. 2, the control device 100 can attached thereto the electronic paper 120 by holding an end of the electronic paper 120 between the control device body 111 and the attachment unit 112, and remove the electronic paper 120 by releasing it.

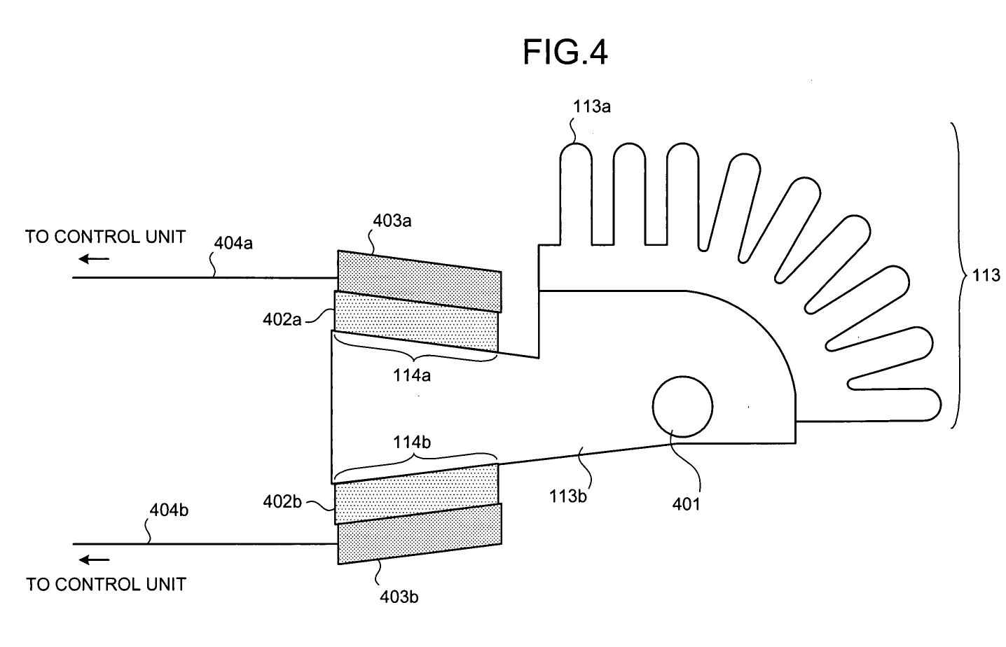

The input device 113 accepts the inputs from the user, and sends the pressure force from the input action to the control device body 111 in the form of a detection signal. The input device 113 includes an input member 113a, a main unit 113b, a first pressure sensor 403a, and a second pressure sensor 403b (see FIG. 4). The user presses the input member 113a with a finger and the like to input an instruction. The main unit 113b reduces the pressure force from the input member 113a and delivers it to pressure sensors to be described later. While the input action is accepted in the form of the pressure force according to the first embodiment, the input action can be accepted as a tensile force and the like if operable by the user's finger.

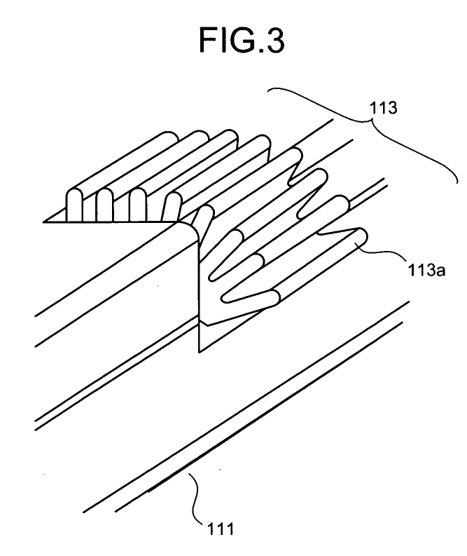

FIG. 3 is an enlarged perspective view for explaining a form of the input member 113a. The input device 113 is attached to the control device body 111. The input member 113a protrudes from the control device body 111 to the outside, and forms radial folds with a plurality of protrusions made of soft material such as silicone. The input member 113a does not necessarily have to be protruding as long as it is exposed so that the user can operate it from the outside of the control device. For example, the input member 113a can be attached into a dent formed on the control device 100 so that the user can operate the input member 113a.

FIG. 4 is a cross section of the input device 113. The main unit 113b has a substantially tabular form with a step near the center thereof and a curve near the end of the main unit 113b, namely from the top of the step to the right end of the main unit 113b in FIG. 4. The input member 113a is attached to the curved portion (near the end) of the main unit 113b, and therefore the folds are radiating from the main unit 113b. The main unit 113b is rotatably supported on the control device body 111 by a fulcrum 401 provided closer to the input member 113a.

The first pressure sensor 403a is disposed on the upper surface of the inner wall of the control device body 111. The upper surface is pressed by an upper portion 114a near the center of the main unit 113b from the left end of the main unit 113b closer to the control device body 111, which is near the end opposite to the position to which the input member 113a is attached to the main unit 113b. The second pressure sensor 403b is disposed on the bottom surface of the inner wall of the control device body 111, and the bottom surface is pressed by a bottom portion 114b near the center of the main unit 113b from the left end of the main unit 113b.

A buffer material 402a is disposed between the upper portion 114a of the main unit 113b and the first pressure sensor 403a. The buffer material 402a absorbs and delivers an impact of the pressure force. Similarly, a buffer material 402b is disposed between the bottom portion 114b of the main unit 113b and the second pressure sensor 403b. Signal lines 404a and 404b extend from the first pressure sensor 403a and the second pressure sensor 403b respectively to a control unit to be described later. While the sensors are used in the first embodiment, other components that detect the pressure force can be used instead of the sensors.

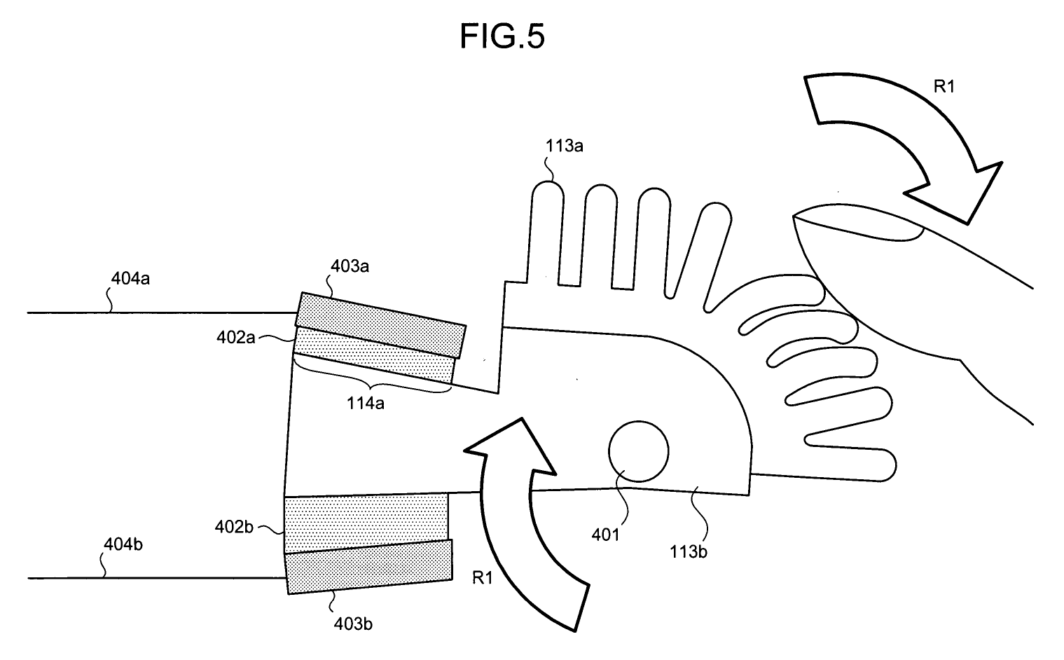

FIG. 5 is a schematic for explaining an input action performed by the user. When the user presses the input member 113a in the direction of R1 (first direction), the input device 113 rotates around the fulcrum 401 in the direction of R1. As a result, the upper portion 114a of the main unit 113b applies pressure force to the first pressure sensor 403a. The first pressure sensor 403a detects the pressure force and delivers the detection signal of the pressure force to the control unit via the signal line 404a.

In the course of the input action, the pressure force input by the user is reduced at three points. The first point is when the user presses the input member 113a. Because the input member 113a is formed by radial folds made of the soft material, the applied pressure force is reduced by the folds bending in the direction of R1. The second point is the fulcrum 401 being provided closer to the input member 113a (outside the main unit of the control device). Because the entire input device 113 operates based on the principle of leverage, the pressure force is reduced. The third point is the buffer material 402a disposed between the upper portion 114a and the first pressure sensor 403a, which absorbs the pressure force. As a result of the pressure force reduced at three points, the applied pressure force is adjusted to achieve fine control.

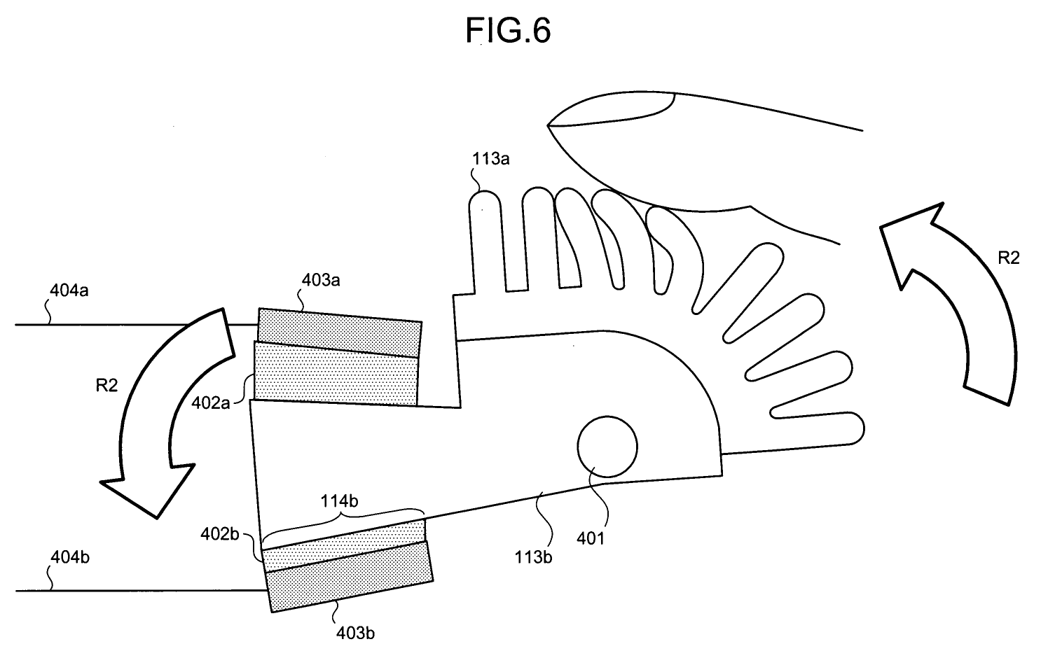

FIG. 6 is a schematic for explaining another input action performed by the user. When the user presses the input member 113a in the direction of R2 (second direction) opposite of the direction of R1, the input device 113 rotates around the fulcrum 401 in the direction of R2. As a result, the bottom portion 114b of the main unit 113b applies pressure force to the second pressure sensor 403b. The second pressure sensor 403b detects the pressure force and delivers the detection signal of the pressure force to the control unit via the signal line 404b.

In the course of the input action, the pressure force input by the user is also reduced at three points allowing for the fine control. When the user presses the input member 113a, the pressure force is reduced in the same manner as the case of pressing the input member 113a in the direction of R1 except for the direction of the folds being pressed.

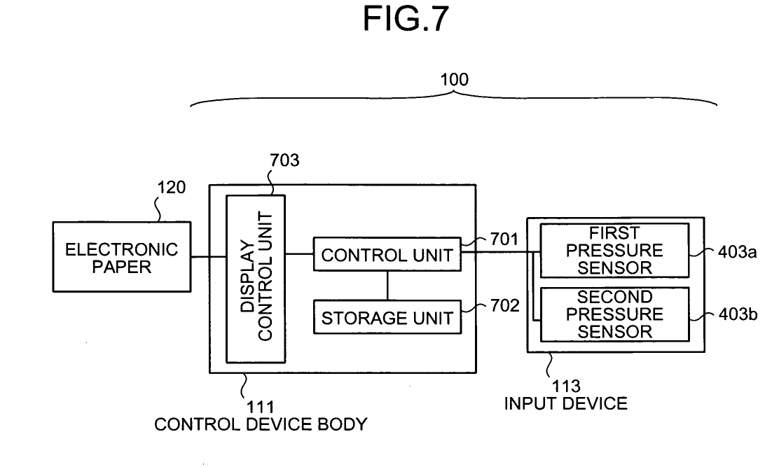

FIG. 7 is a block diagram of the control device 100. The control device 100 includes the input device 113 and the control device body 111. The input device 113 includes the first pressure sensor 403a and the second pressure sensor 403b as described above, and the control device body 111 includes a control unit 701, a storage unit 702, and a display control unit 703.

The input device 113 accepts inputs from the user, and sends the pressure force from the input action to the control device body 111 in the form of the detection signal.

The first pressure sensor 403a detects the level of the pressure force from the voltage that changes depending on the level of the pressure force applied by the user, and outputs the level of the pressure force in the form of the detection signal. More specifically, the first pressure sensor 403a detects the pressure force delivered from the main unit 113b and delivers it to the control unit 701 in the control device body 111. The first pressure sensor 403a is disposed in a position to be pressed by the upper portion 114a of the main unit 113b closer to the control device body 111 (see FIG. 4) rotating in the first direction (see FIG. 5) around the fulcrum when the input member 113a is rotated in the first direction by the user.

The second pressure sensor 403b detects the level of the pressure force from the voltage that changes depending on the level of the pressure force applied by the user, and outputs the level of the pressure force in the form of the detection signal. More specifically, the second pressure sensor 403b detects the pressure force delivered from the main unit 113b and delivers it to the control unit 701 in the control device body 111. The second pressure sensor 403b is disposed in a position to be pressed by the bottom portion 114b of the main unit 113b closer to the control device body 111 (see FIG. 4) rotating in the second direction (see FIG. 6) around the fulcrum when the input member 113a is rotated in the second direction by the user.

The control unit 701 receives the detection signals from the first pressure sensor 403a and the second pressure sensor 403b in the input device 113, and controls the function of displaying the data in the display control unit 703 based on the detection signals. More specifically, the control unit 701 determines the amount of pages of text or image data switched at a time (hereinafter, “switched page amount”) to be displayed on the electronic paper 120 based on the detected pressure force, the duration of the pressure force, and the pressing speed. The duration of the pressure force herein refers to the time of receiving the detection signals from the pressure sensor. The pressing speed corresponds to the pressure force in a predetermined time, namely the pressure strength divided by the time (duration). A page herein is a unit of the data displayed on the electronic paper 120 at a time.

When the upper portion 114a returns in the second direction due to the reaction of the pressure force to the first pressure sensor 403a, the control unit 701 neutralizes the pressure force detected from the bottom portion 114b. Similarly, when the bottom portion 114b returns in the first direction due to the reaction of the pressure force to the second pressure sensor 403b, the control unit 701 neutralizes the pressure force detected from the upper portion 114a. This reduces noise in the input device 113.

When the control unit 701 detects the pressure force from the first pressure sensor 403a, the control unit 701 determines to advance the pages of the data on the electronic paper 120, namely a page advance. On the contrary, when the control unit 701 detects the pressure force from the second pressure sensor 403b, the control unit 701 determines to return the pages of the data on the electronic paper 120, namely a page rewind.

The storage unit 702 is a recording medium such as a memory that stores therein the data to be displayed.

The display control unit 703 displays the data in the storage unit 702 on the electronic paper 120 based on the displaying operation determined by the control unit 701. More specifically, when the control unit 701 determines to advance the pages of the data to be displayed on the electronic paper 120, the display control unit 703 displays the advanced pages of the data on the electronic paper 120. On the contrary, when the control unit 701 determines to rewind the pages of the data to be displayed, the display control unit 703 displays former pages of the data on the electronic paper 120.

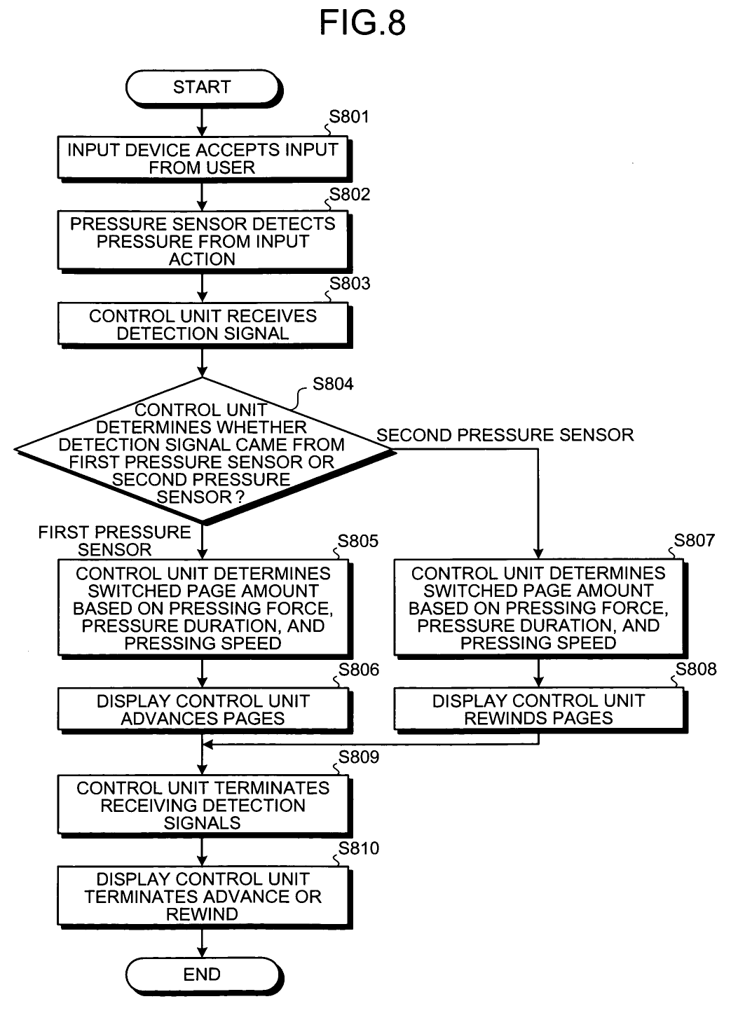

FIG. 8 is a flowchart of a procedure for switching contents of data to be displayed using the control device 100.

The input device 113 accepts the input from the user via the input member 113a (step S801). One of the first pressure sensor 403a and the second pressure sensor 403b detects the pressure forces accepted by the input device 113 (step S802), and sends detection signals indicative of the pressure force to the control unit 701. The control unit 701 receives the detection signal from the pressure sensor (step S803).

The control unit 701 determines whether the detection signal was sent from the first pressure sensor 403a or the second pressure sensor 403b (step S804).

If the detection signal was sent from the first pressure sensor 403a (FIRST PRESSURE SENSOR at step S804), the control unit 701 determines the switched page amount of the data based on the level of the pressure force, the duration of the pressure force, and the pressing speed received from the first pressure sensor 403a (step S805).

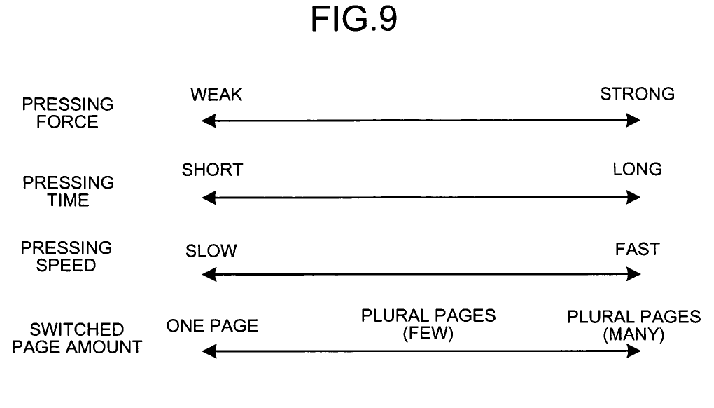

FIG. 9 is a schematic for explaining how the control unit 701 determines the switched page amount. In terms of the level of the pressure force, the control unit 701 determines to switch a single page when the pressure force is weak, and the switched page amount increases as the pressure force increases.

In terms of the duration (hereinafter, “time”) of the pressure force, the control unit 701 determines to switch a single page when the time of the pressure force is short, and the switched page amount increases as the time extends. In terms of the pressing speed, the control unit 701 determines to switch a single page when the speed of the pressure force is slow, and the switched page amount increases as the speed increases. In this manner, use of the input device 113 in the electronic paper 120 is advantageous in that pages can be switched on the electronic paper 120 as easily as turning pages of paper books.

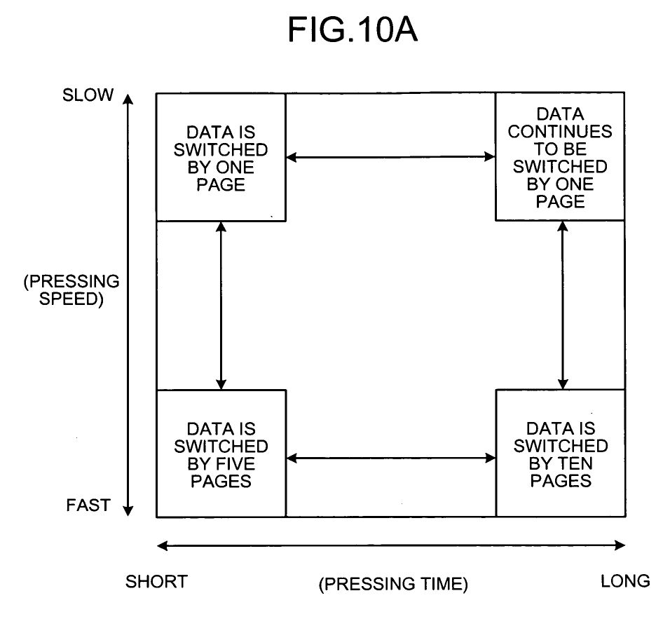

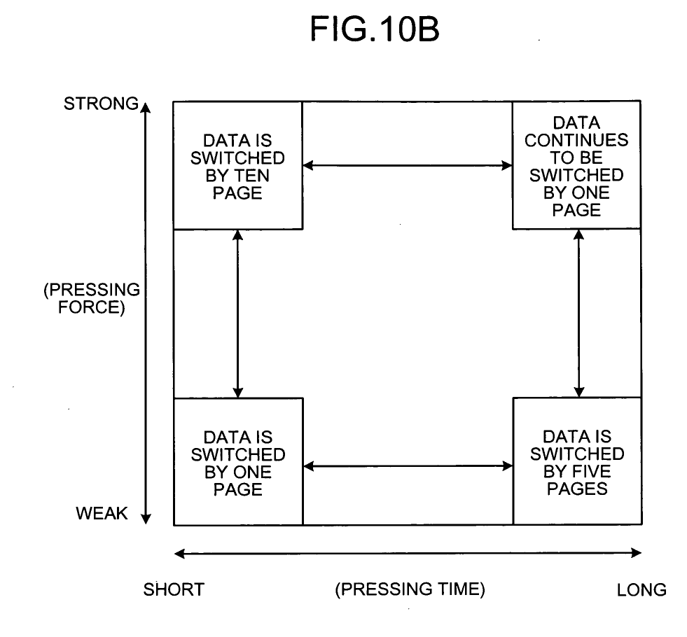

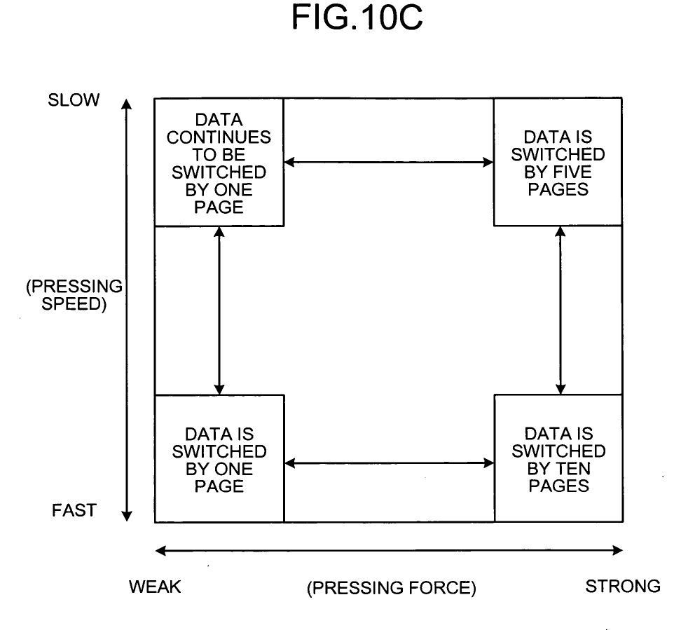

FIG. 10A is a schematic for explaining a case of the control unit 701 determining the switched page amount based on the pressing speed and the pressing time. When the pressing speed is slow and the pressing time is short, the data is switched by a single page, and when the pressing speed is slow and the pressing time is long, the data continues to be switched by a single page. When the pressing speed is fast and the pressing time is short, the data is switched by the unit of five pages, and when the pressing speed is fast and the pressing time is long, the data is switched by the unit of ten pages. Because there are more than two levels of each parameter, for example, the data can be switched by seven pages or eight pages when the pressure speed is fast and the pressing time is medium.

FIG. 10B is a schematic for explaining a case of determining the switched page amount based on the level of the pressure force and the pressing time. When the pressure force is strong and the pressing time is short, the data is switched by the unit of ten pages, and when the pressure force is strong and the pressing time is long, the data continues to be switched by a single page. When the pressure force is weak and the pressing time is short, the data is switched by a single page, and when the pressure force is weak and the pressing time is long, the data is switched by the unit of five pages. There are more than two levels of each parameter as with the case in FIG. 10A.

FIG. 10C is a schematic for explaining a case of determining the switched page amount based on the pressing speed and the level of the pressure force. When the pressing speed is slow and the pressure force is weak, the data continues to be switched by a single page, and when the pressing speed is slow and the pressure force is strong, the data is switched by the unit of five pages. When the pressing speed is fast and the pressure force is weak, the data is switched by a single page, and when the pressing speed is fast and the pressure force is strong, the data is switched by the unit of ten pages. There are more than two levels of each parameter as with the cases in FIGS. 10A and 10B.

Returning to the explanation of the procedure using FIG. 8, when the control unit 701 determines the switched page amount on the electronic paper 120, the display control unit 703 advances pages according to the determination, and displays the corresponding page on the electronic paper 120 (step S806).

On the other hand, if the detection signal was sent from the second pressure sensor 403b (SECOND PRESSURE SENSOR at step S804), the control unit 701 determines the switched page amount of the data displayed on the electronic paper 120 based on the level of the pressure force, the pressing time, and the pressing speed received from the second pressure sensor 403b (step S807). When the control unit 701 determines the switched page amount, the display control unit 703 rewinds pages according to the determination, and displays the corresponding page on the electronic paper 120 (step S808).

The control unit 701 terminates receiving the detection signals of the pressure force from the pressure sensors (step S809). The display control unit 703 terminates the process of the page advance or the page rewind (step S810).

In this manner, according to the first embodiment, an input is received in the form of pressure force via the input member 113a, the first pressure sensor 403a and the second pressure sensor 403b detect the operating force, and the input device 113 sends detection signals indicative of the detected force to the control device body 111. The control unit 701 determines the displaying operation based on the level, the time, and the speed of the detected pressure force, and the display control unit 703 displays the data stored in the storage unit 702 on the electronic paper 120 according to the displaying operation.

Because the input member 113a is made of the soft elastic material forming folds thereon, a finger of the user hardly slips, and absorption of the pressure force realizes control by the subtle force input from the finger with only one hand, resulting in prevention of hurting the finger. Because the operation can be performed with a single finger, it is easy for aged or disabled people who are weak in the hand. It is also easy to recognize the input device at one view.

Because the fulcrum 401 is provided based on the principle of leverage, the pressure force is reduced and finely controlled. Force of the input member 113a bouncing back from the pressure force by the input action is delivered to the finger, and the input device 113 presses the first pressure sensor 403a and the second pressure sensor 403b based on the principle of leverage without rotating 360 degrees. This helps the user to know the start point and the end point of a single operation. Furthermore, absorption of the pressure force by the buffer materials 402a and 402b enables the control by the subtler pressure force.

Because the pressure force is reduced and delivered, when the contents of data to be displayed is advanced or rewound based on the level, the time, and the speed of the pressure force, the displaying operation can be finely controlled, and the input can be performed both intermittently and continuously. Because the input is performed by detecting the pressure force, the sliding action is not required, and therefore wear of material can be prevented. Moreover, because the operation corresponding to each input action can be specified by determining which pressure sensor is pressed, various operations can be determined according to the application of the control device 100. By neutralizing the pressure force as a reaction to the pressure force by the first pressure sensor 403a or the second pressure sensor 403b when it is converted into electric signals, the noise can be reduced during the operation.

While the fulcrum 401 is closer to the input member 113a according to the first embodiment, the position of the fulcrum 401 can be changed to, for example, closer to the control device 100, or the fulcrum 401 can be configured to hardly rotate so that the input force is reduced and delivered to the first pressure sensor 403a or the second pressure sensor 403b. The forms of the buffer materials 402a and 402b can be changed according to the degree of the easiness.

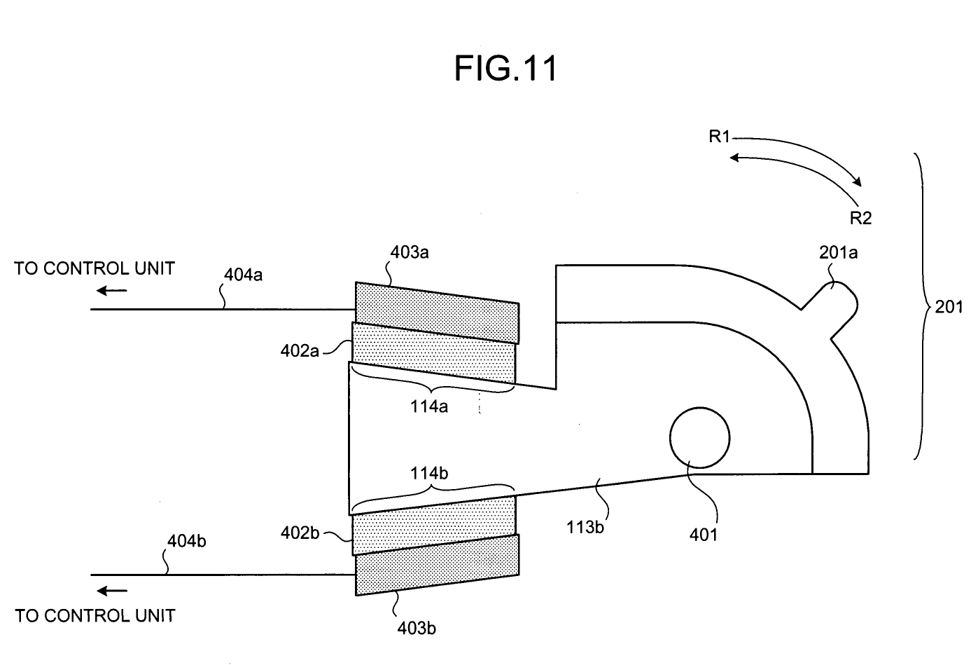

FIG. 11 is a cross section of an input device 201 according to a second embodiment of the present invention.

A user presses an input member 201a with a finger and the like to input an instruction. The input member 201a is attached to the main unit 113b from the top of the step to the curved portion (near the end). The input member 201a includes a single protrusion by which the user can perform the input operation, and the input member 201a is made of a soft material such as silicone like the input member 113a according to the first embodiment of the present invention.

When the user presses the protrusion of the input member 201a in the direction of R1 (the first direction), the input device 201 rotates around the fulcrum 401 in the direction of R1. When the user presses the protrusion of the input member 201a in the direction of R2 (the second direction) opposite of R1, the input device 201 rotates around the fulcrum 401 in the direction of R2.

Because the input member 201a according to the second embodiment has a single protrusion and is made of the soft material provided over a surface of the main unit 113b, a finger of the user hardly slips, and absorption of the pressure force realizes the control by the subtle force input from the finger with only one hand. It is also easy to recognize the input device at one view. Furthermore, the reduced operation force realizes the fine control and the input can be detected no matter it is intermittent or continuous. Because the input is performed by detecting the pressure force, the sliding action is not required and therefore wear of material can be prevented.

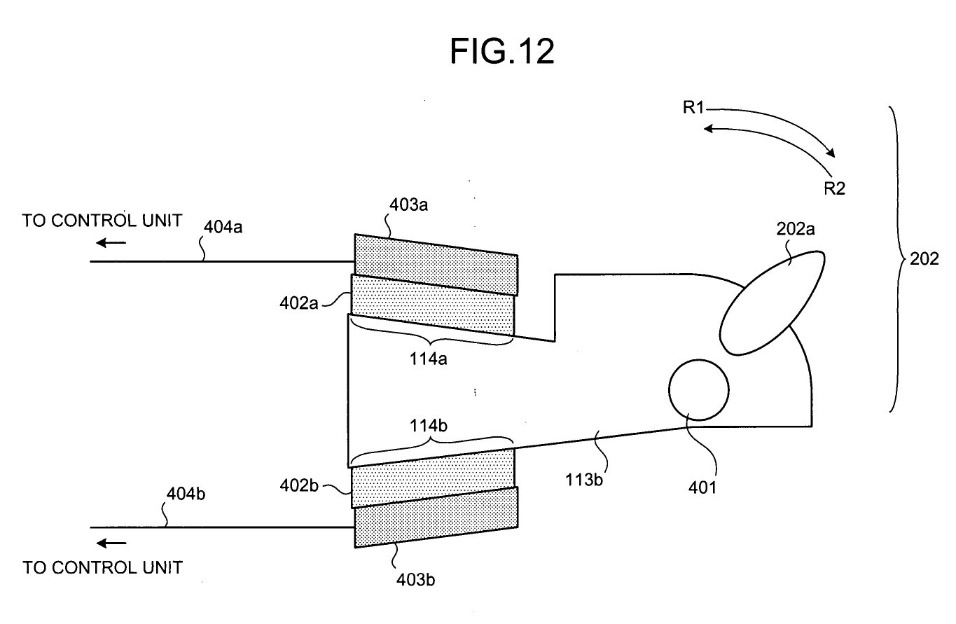

FIG. 12 is a cross section of an input device 202 according to a third embodiment of the present invention. In addition to the explanation according to the first embodiment, the main unit 113b further includes a dent on the curved portion near the end of the main unit 113b.

A user presses an input member 202a with a finger and the like to input an instruction. The input member 202a is engaged with the dent on the curved portion of the main unit 113b. The input member 202a has a substantially oval cross section, protrudes from the main unit 113b, and is made of a soft material such as silicone like the input member 113a according to the first embodiment. While the cross section of the input member 202a according to the third embodiment is substantially oval, the shape of the cross section is not limited by the third embodiment, and can be another shape such as a circle, a rectangle, or the like, as long as it receives the user's finger to detect bidirectional forces input by the finger.

When the user presses the input member 202a protruding from the main unit 113b in the direction of R1, the input device 202 rotates around the fulcrum 401 in the direction of R1. When the user presses the input member 202a in the direction of R2 opposite of R1, the input device 202 rotates around the fulcrum 401 in the direction of R2.

Because the input member 202a according to the third embodiment is made of the soft material with the oval cross section protruding from the main unit 113b, a finger of the user hardly slips, and absorption of the pressure force realizes the control by the subtle force input from the finger with only one hand. It is also easy to recognize the input device at one view. Furthermore, the fine control can be realized, the input can be detected no matter it is intermittent or continuous, and wear of material can be prevented like the input member 201a according to the second embodiment.

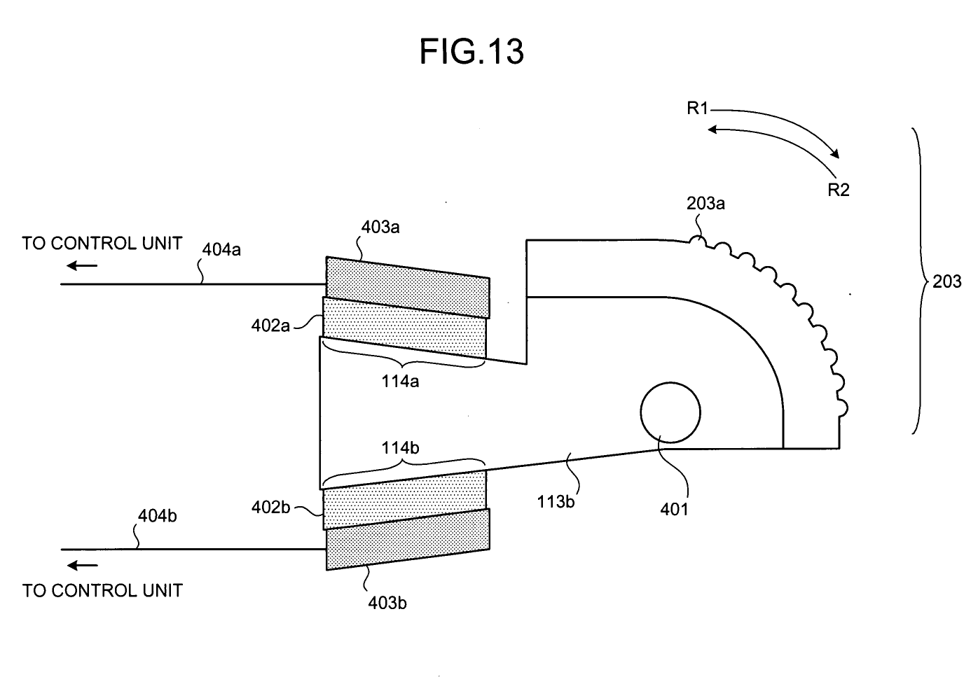

FIG. 13 is a cross section of an input device 203 according to a fourth embodiment of the present invention.

A user presses an input member 203a with a finger and the like to input an instruction. The input member 203a is attached to the main unit 113b from the top of the step to the curved portion. The input member 203a includes a plurality of hemispherical protrusions by which the user can perform the input operation, and the input member 203a is made of a soft material such as silicone like the input member 113a according to the first embodiment. While the cross section of each protrusion on the input member 203a according to the fourth embodiment is hemispherical, the shape of the cross section is not limited by the fourth embodiment, and can be another shape such as a rectangle, a triangle, or the like, as long as it receives the user's finger to detect bidirectional forces input by the finger.

When the user presses the protrusions of the input member 203a in the direction of R1, the input device 203 rotates around the fulcrum 401 in the direction of R1. When the user presses the protrusions of the input member 203a in the direction of R2 opposite of R1, the input device 203 rotates around the fulcrum 401 in the direction of R2.

Because the input member 203a according to the fourth embodiment is made of the soft material provided over a surface of the main unit 113b and has a plurality of protrusions thereon, a finger of the user hardly slips, and absorption of the pressure force realizes the control by the subtle force input from the finger with only one hand. It is also easy to recognize the input device at one view. Furthermore, the fine control can be realized, the input can be detected no matter it is intermittent or continuous, and wear of material can be prevented like the input member 201a according to the second embodiment.

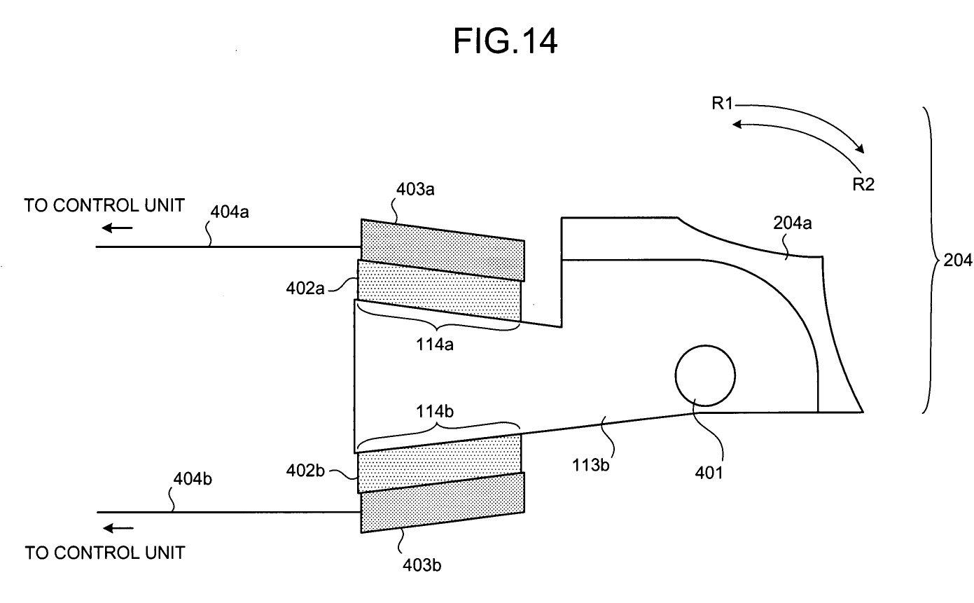

FIG. 14 is a cross section of an input device 204 according to a fifth embodiment of the present invention.

A user presses an input member 204a with a finger and the like to input an instruction. The input member 204a is attached to the main unit 113b from the top of the step to the curved portion. The input member 204a includes two incurves over a surface of the main unit 113b, an intersection of the two curved portions convex by which the user can perform the input operation, and the input member 204a is made of a soft material such as silicone like the input member 113a according to the first embodiment. While the input member 204a according to the fifth embodiment forms two incurves, the number of the incurves is not limited by the fifth embodiment, and there can be three or more incurves, as long as the input member receives the user's finger to detect bidirectional forces input by the finger.

When the user presses the intersection of the incurves of the input member 204a in the direction of R1, the input device 204 rotates around the fulcrum 401 in the direction of R1. When the user presses the intersection of the incurves of the input member 204a in the direction of R2 opposite of R1, the input device 204 rotates around the fulcrum 401 in the direction of R2.

Because the input member 204a according to the fifth embodiment is made of the soft material provided over a surface of the main unit 113b and has two incurves forming a convex intersection thereon, a finger of the user hardly slips, and absorption of the pressure force realizes the control by the subtle force input from the finger with only one hand. It is also easy to recognize the input device at one view. Furthermore, the fine control can be realized, the input can be detected no matter it is intermittent or continuous, and wear of material can be prevented like the input member 201a according to the second embodiment.

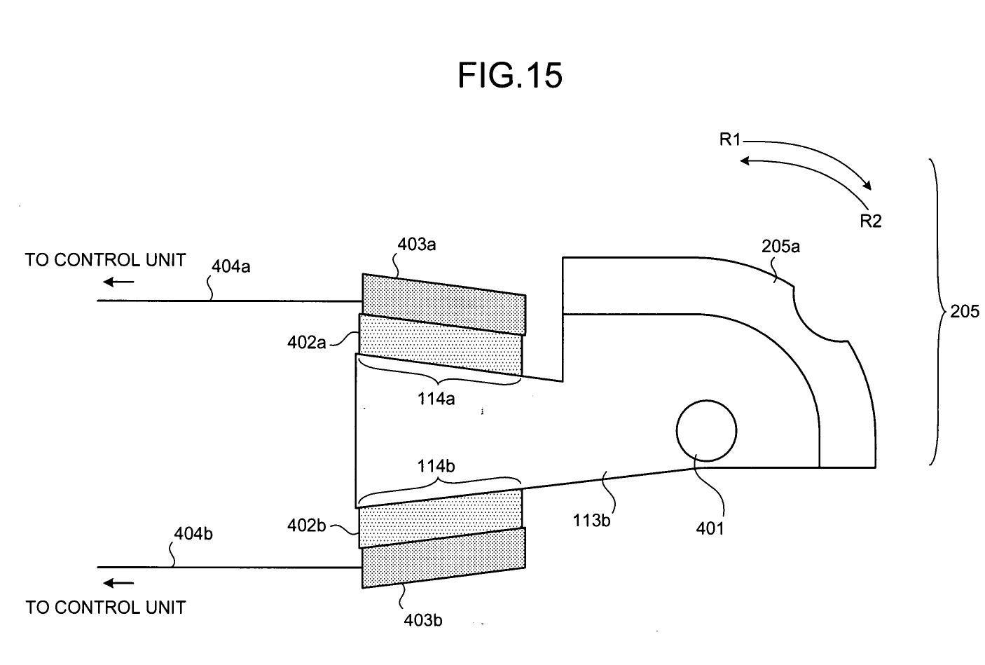

FIG. 15 is a cross section of an input device 205 according to a sixth embodiment of the present invention.

A user presses an input member 205a with a finger and the like to input an instruction. The input member 205a is attached to the main unit 113b from the top of the step to the curved portion. The input member 205a includes a single dent by which the user can perform the input operation, and the input member 205a is made of a soft material such as silicone like the input member 113a according to the first embodiment.

When the user presses the dent of the input member 205a in the direction of R1, the input device 205 rotates around the fulcrum 401 in the direction of R1. When the user presses the dent of the input member 205a in the direction of R2 opposite of R1, the input device 205 rotates around the fulcrum 401 in the direction of R2.

Because the input member 205a according to the sixth embodiment has a single dent and is made of the soft material provided over a surface of the main unit 113b, a finger of the user hardly slips, and absorption of the pressure force realizes the control by the subtle force input from the finger with only one hand. It is also easy to recognize the input device at one view. Furthermore, the fine control can be realized, the input can be detected no matter it is intermittent or continuous, and wear of material can be prevented like the input member 201a according to the second embodiment.

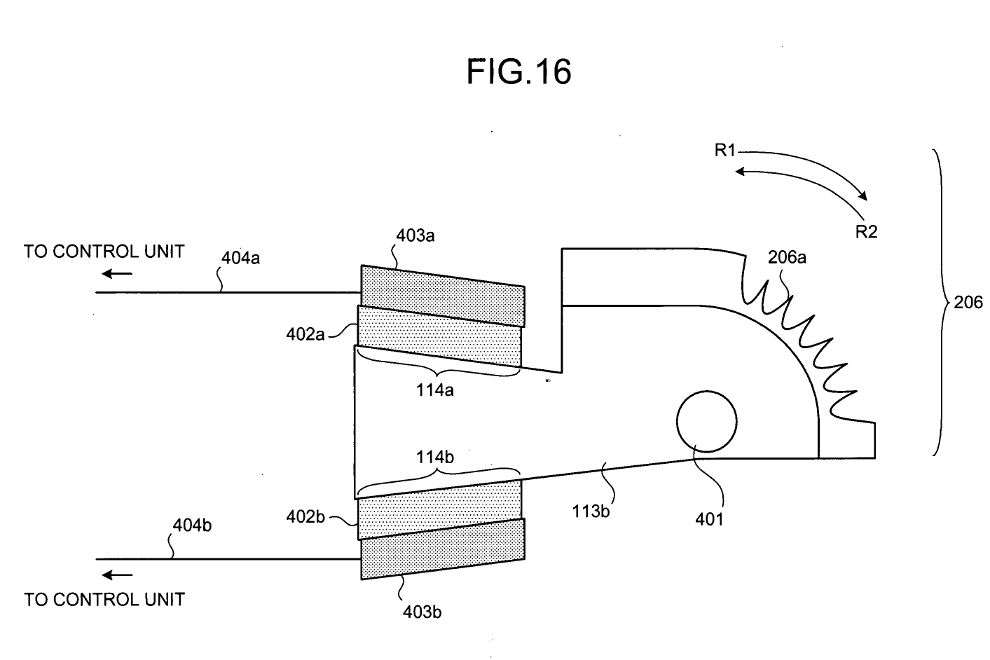

FIG. 16 is a cross section of an input device 206 according to a seventh embodiment of the present invention.

A user presses an input member 206a with a finger and the like to input an instruction. The input member 206a is attached to the main unit 113b from the top of the step to the curved portion. The input member 206a includes a concave portion on a surface thereof and a plurality of folded protrusions in the concave portion by which the user can perform the input operation, and the input member 206a is made of a soft material such as silicone like the input member 113a according to the first embodiment.

When the user presses the folded protrusions of the input member 206a in the direction of R1, the input device 206 rotates around the fulcrum 401 in the direction of R1. When the user presses the folded protrusions of the input member 206a in the direction of R2 opposite of R1, the input device 206 rotates around the fulcrum 401 in the direction of R2.

Because the input member 206a according to the seventh embodiment is made of the soft material provided over a surface of the main unit 113b and has a plurality of folded protrusions in the concave portion thereon, a finger of the user hardly slips, and absorption of the pressure force realizes the control by the subtle force input from the finger with only one hand. It is also easy to recognize the input device at one view. Furthermore, the fine control can be realized, the input can be detected no matter it is intermittent or continuous, and wear of material can be prevented like the input member 201a according to the second embodiment.

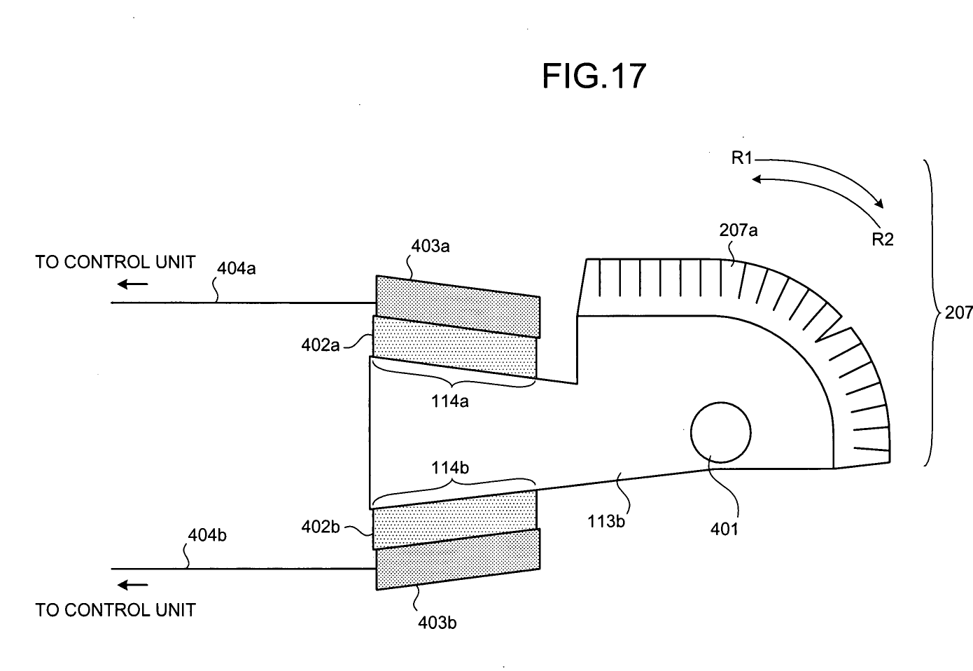

FIG. 17 is a cross section of an input device 207 according to an eighth embodiment of the present invention.

A user presses an input member 207a with a finger and the like to input an instruction. The input member 207a is attached to the main unit 113b from the top of the step to the curved portion. The input member 207a includes a plurality of cuts on a surface thereof by which the user can perform the input operation, and the input member 207a is made of a soft material such as silicone like the input member 113a according to the first embodiment.

When the user presses the cuts in the input member 207a in the direction of R1, the input device 207 rotates around the fulcrum 401 in the direction of R1. When the user presses the cuts in the input member 207a in the direction of R2 opposite of R1, the input device 207 rotates around the fulcrum 401 in the direction of R2.

Because the input member 207a according to the eighth embodiment is made of the soft material provided over a surface of the main unit 113b and has a plurality of cuts vertical to the surface, a finger of the user hardly slips, and absorption of the pressure force realizes the control by the subtle force input from the finger with only one hand. It is also easy to recognize the input device at one view.

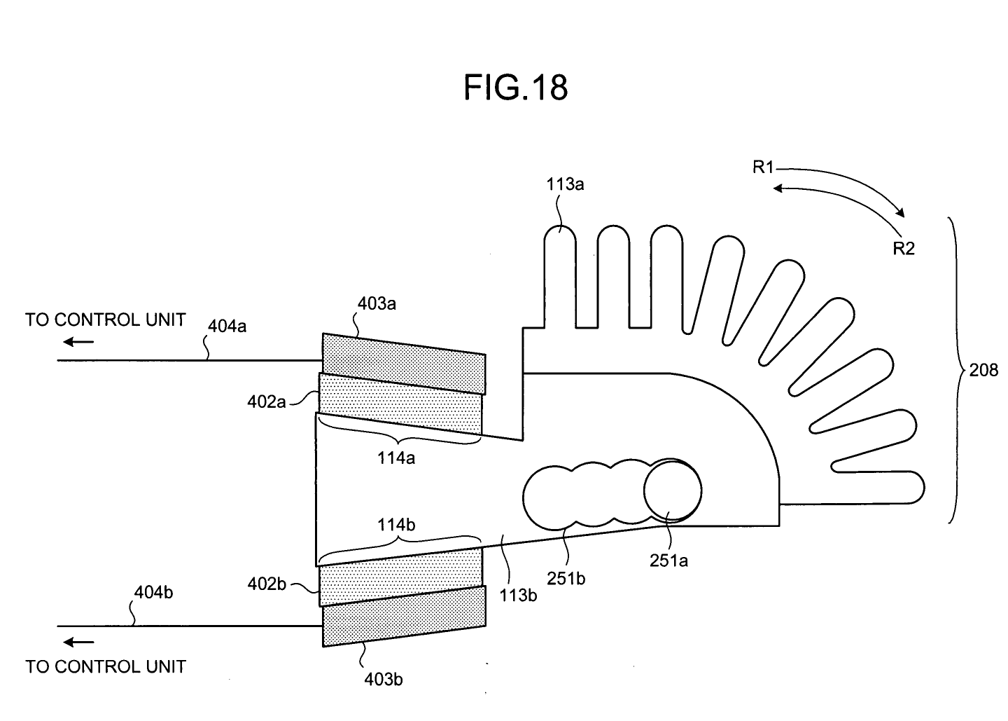

FIG. 18 is a cross section of an input device 208 according to a ninth embodiment of the present invention.

The main unit 113b reduces the pressure force of an input from the input member 113a and delivers it to the pressure sensors. The main unit 113b has a substantially tabular form with a step near the center thereof and a curve near the end of the main unit 113b, namely from the top of the step to the right end of the main unit 113b in FIG. 18. The main unit 113b is rotatably supported on a control device body (not shown) by a fulcrum 251a movably provided closer to the input member 113a.

The fulcrum 251a is configured to move between an effort point at which a user performs the input action and a load point near the end of the main unit 113b opposite to the input member 113a. In other words, the main unit 113b includes a hole 251b formed in the shape of sequential circles between the effort point and the load point. The user can move the fulcrum 251a by switching the position thereof to any of the circles in the hole 251b.

When the user presses the effort point on the input member 113a in the direction of R1, the input device 208 rotates around the fulcrum 251a in the direction of R1. When the user presses the effort point on the input member 113a in the direction of R2 opposite of R1, the input device 208 rotates around the fulcrum 251a in the direction of R2. The operating force is reduced more when the fulcrum 251a is closer to the load point than to the effort point.

Because the fulcrum 251a is configured to move between the effort point and the load point, the user can switch the position of the fulcrum 251a, whereby the level of the force required for the input action can be adjusted.

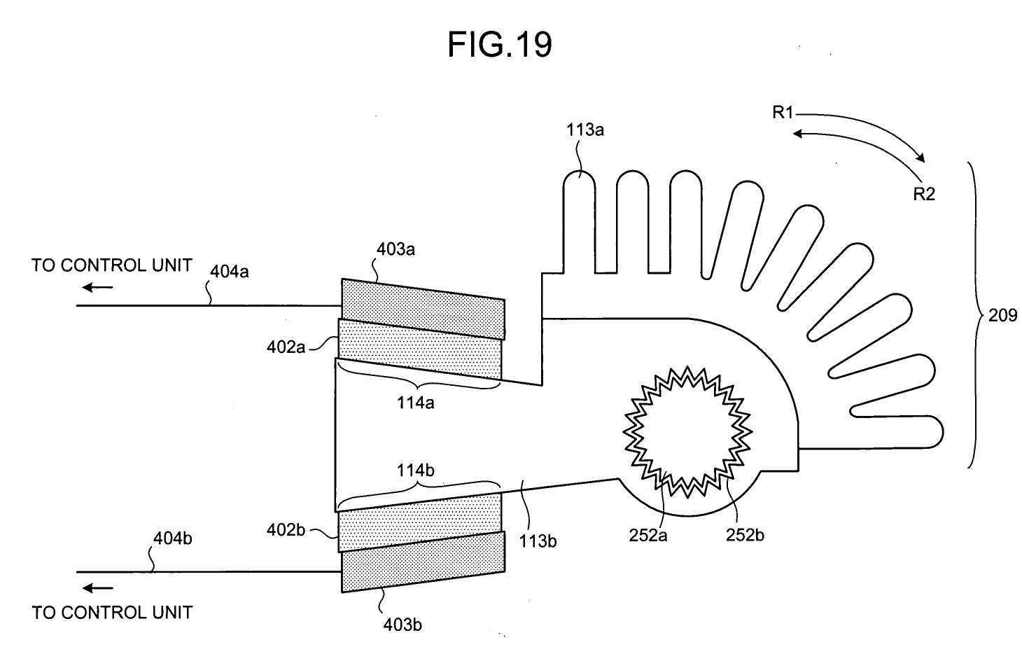

FIG. 19 is a cross section of an input device 209 according to a tenth embodiment of the present invention.

The main unit 113b reduces the pressure force of an input from the input member 113a and delivers it to the pressure sensors. The main unit 113b has a substantially tabular form with a step near the center thereof and a curve near the end of the main unit 113b, namely from the top of the step to the right end of the main unit 113b in FIG. 19. The main unit 113b includes a hole through which a fulcrum 252a passes, and is rotatably supported on a control device body (not shown) by the fulcrum 252a provided through the hole.

An outer circumference of the fulcrum 252a is knurled. An inner wall 252b of the hole is also knurled to fit the outer circumference of the fulcrum 252a.

When a user presses the input member 113a in the direction of R1, the input device 209 rotates around the fulcrum 252a in the direction of R1. When the user presses the input member 113a in the direction of R2 opposite of R1, the input device 209 rotates around the fulcrum 252a in the direction of R2. When the input device 209 rotates in any one of directions R1 and R2, the knurled outer circumference of the fulcrum 252a contacts the inner wall 252b of the hole to produce resistance.

Because the outer circumference of the fulcrum 252a and the inner wall 252b of the hole are knurled, the resistance produced by the contact between the fulcrum 252a and the hole reduces the operating force enabling control by subtle force of the finger.

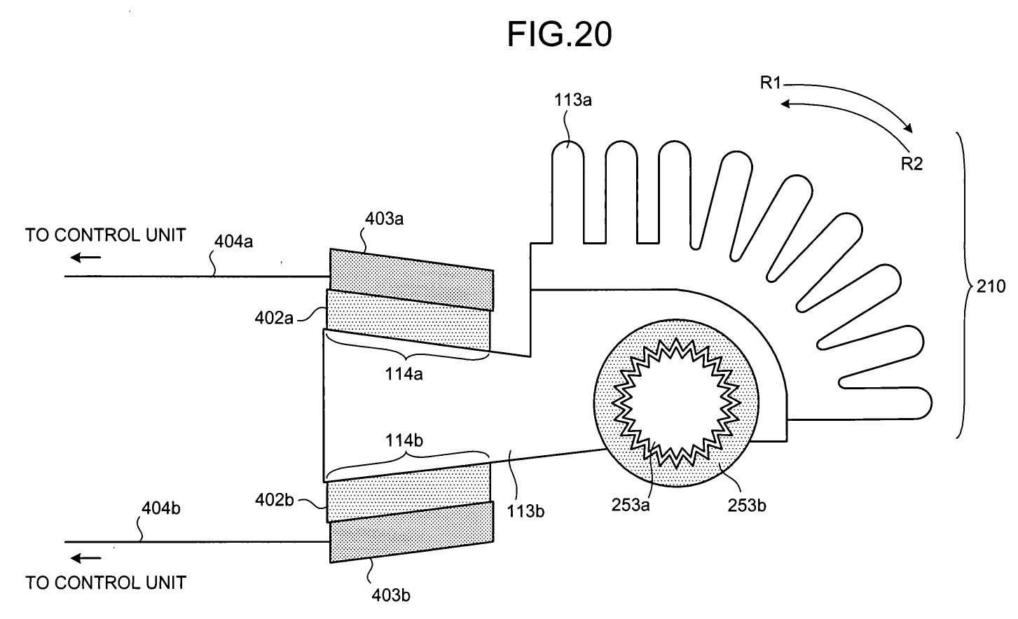

FIG. 20 is a cross section of an input device 210 according to an eleventh embodiment of the present invention.

The main unit 113b reduces the pressure force of an input from the input member 113a and delivers it to the pressure sensors. The main unit 113b has a substantially tabular form with a step near the center thereof and a curve near the end of the main unit 113b, namely from the top of the step to the right end of the main unit 113b in FIG. 20. The main unit 113b includes a hole through which a fulcrum 253a passes, and is rotatably supported on a control device body (not shown) by the fulcrum 253a provided through the hole.

An outer circumference of the fulcrum 253a is knurled. An inner wall 253b of the hole is also knurled to fit the outer circumference of the fulcrum 253a, and made of a soft material.

When a user performs an input action, the input device 210 rotates around the fulcrum 253a in any one of directions R1 and R2. When the input device 210 rotates in any one of directions R1 and R2, the knurled outer circumference of the fulcrum 253a contacts the inner wall 253b of the hole made of the soft material to produce resistance.

Because the inner wall 253b of the hole in the main unit 113b is made of the soft material, the resistance produced by the contact between the knurled outer circumference of the fulcrum 253a and the inner wall 253b of the hole reduces the operating force enabling the control by the subtler force of the finger.

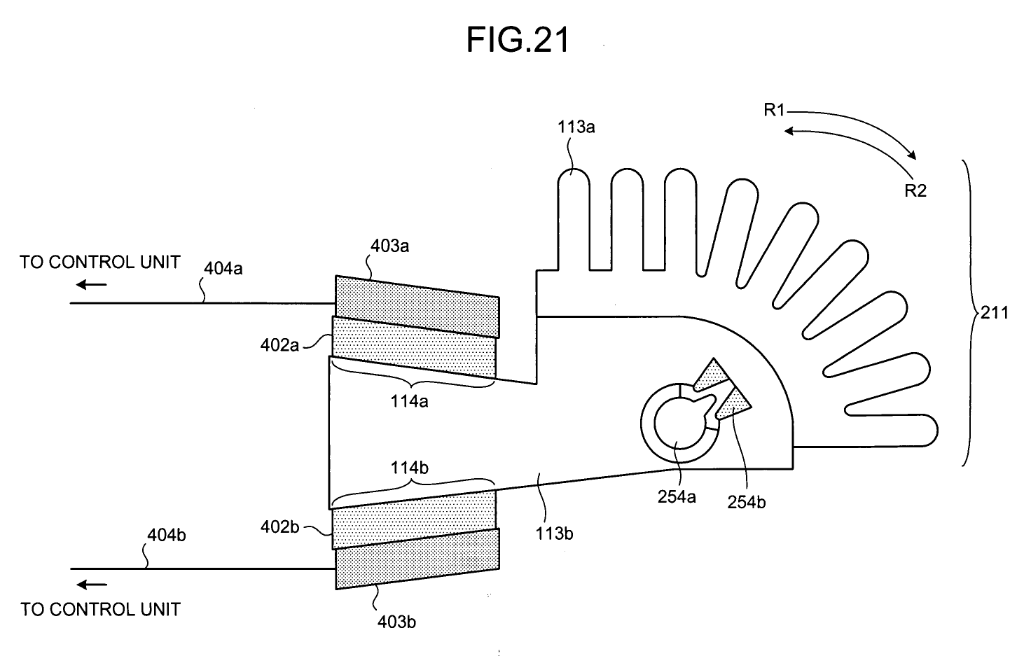

FIG. 21 is a cross section of an input device 211 according to a twelfth embodiment of the present invention.

The main unit 113b reduces the pressure force of an input from the input member 113a and delivers it to the pressure sensors. The main unit 113b has a substantially tabular form with a step near the center thereof and a curve near the end of the main unit 113b, namely from the top of the step to the right end of the main unit 113b in FIG. 21. The main unit 113b is rotatably supported on a control device body (not shown) by a fulcrum 254a.

The fulcrum 254a includes a single protrusion. The main unit 113b includes two protrusions 254b made of a soft material so as to hold the single protrusion on the fulcrum 254a in between from the opposite direction. While the protrusions 254b are made of the soft material according to the twelfth embodiment, the single protrusion on the fulcrum 254a can be made of the soft material instead.

When a user performs an input action, the input device 211 rotates around the fulcrum 254a in any one of directions R1 and R2. When the input device 211 rotates in any one of directions R1 and R2, the single protrusion on the fulcrum 254a contacts the protrusions 254b on the main unit 113b to produce resistance.

Because the fulcrum 254a includes a single protrusion and the main unit 113b includes the two protrusions 254b that hold the single protrusion in between, the resistance produced by the contact between the single protrusion on the fulcrum 254a and the protrusions 254b reduces the operating force enabling the control by the subtle force of the finger.

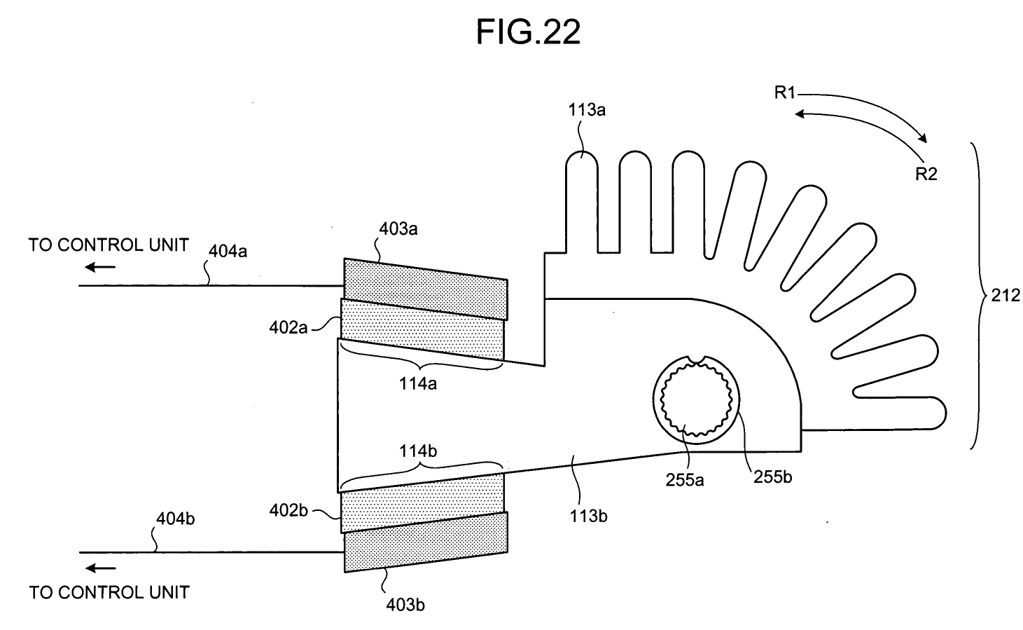

FIG. 22 is a cross section of an input device 212 according to a thirteenth embodiment of the present invention.

The main unit 113b reduces the pressure force of an input from the input member 113a and delivers it to the pressure sensors. The main unit 113b has a substantially tabular form with a step near the center thereof and a curve near the end of the main unit 113b, namely from the top of the step to the right end of the main unit 113b in FIG. 22. The main unit 113b is rotatably supported on a control device body (not shown) by a fulcrum 255a.

An outer circumference of the fulcrum 255a is knurled. An inner wall 255b of a hole in the main unit 113b includes a single protrusion that contacts the knurled circumference of the fulcrum 255a.

When a user performs an input action, the input device 212 rotates around the fulcrum 255a in any one of directions R1 and R2. When the input device 212 rotates in any one of directions R1 and R2, the knurled outer circumference of the fulcrum 255a contacts the single protrusion on the inner wall 255b to produce resistance.

Because the outer circumference of the fulcrum 255a is knurled and the inner wall 252b of the hole has a single protrusion, the resistance produced by the contact between the knurled circumference of the fulcrum 255a and the protrusion in the main unit 113b reduces the operating force enabling the control by the subtle force of the finger.

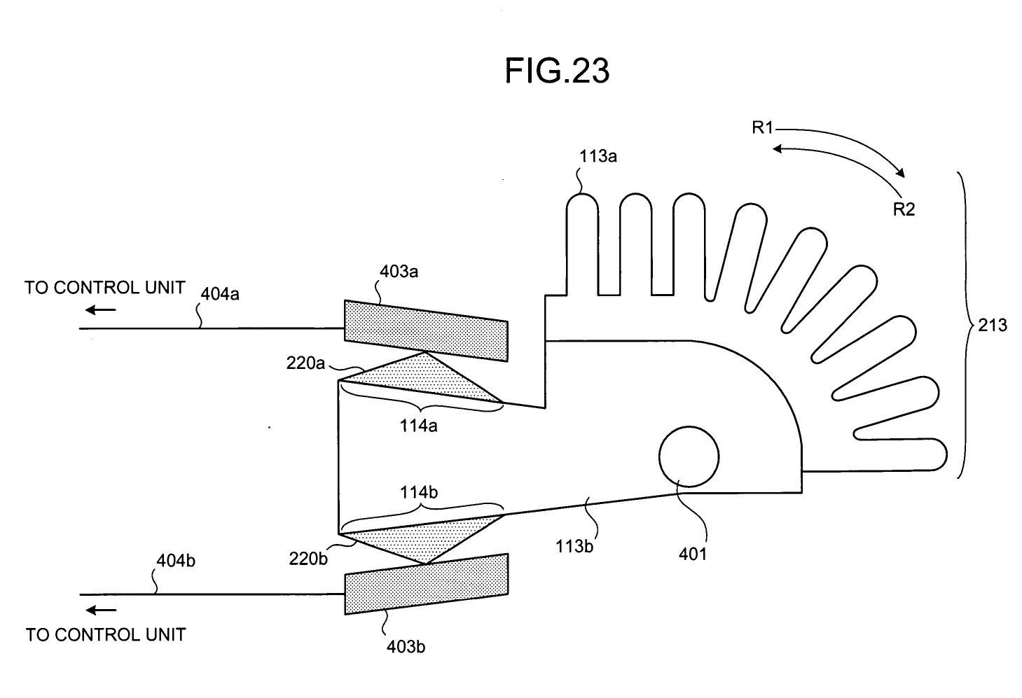

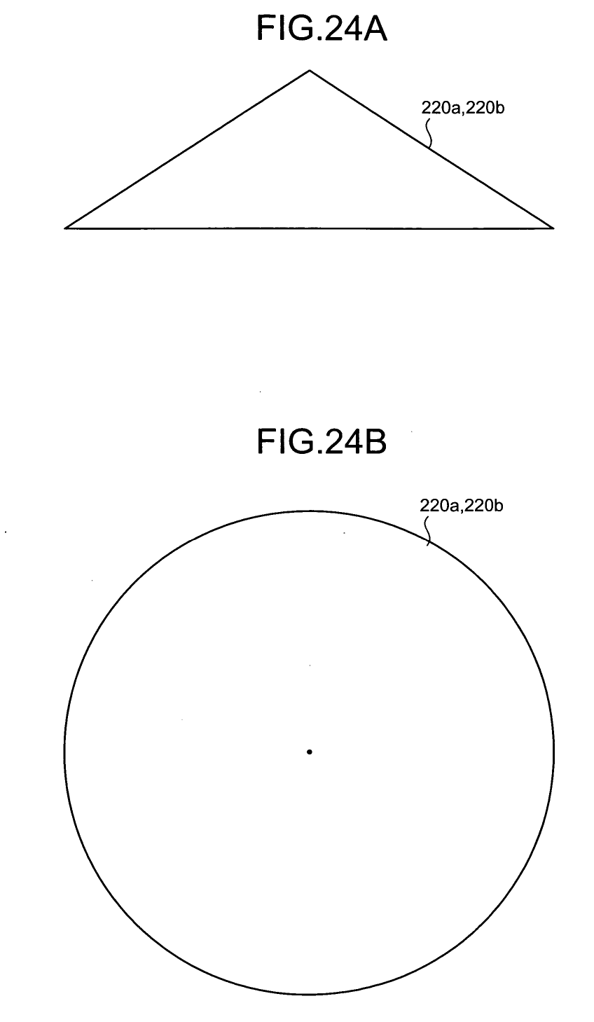

FIG. 23 is a cross section of an input device 213 according to a fourteenth embodiment; FIG. 24A is a cross section of buffer materials 220a and 220b shown in FIG. 23; and FIG. 24B is a top view of the buffer materials 220a and 220b.

The buffer material 220a is provided between the upper portion 114a of the main unit 113b and the first pressure sensor 403a to reduce the impact of the pressure force by absorbing it and deliver it to the first pressure sensor 403a. The buffer materials 220b is also provided between the bottom portion 114b of the main unit 113b and the second pressure sensor 403b to reduce the impact of the pressure force by absorbing it and deliver it to the second pressure sensor 403b. The buffer materials 220a and 220b have an isosceles-triangular cross section, and form a conical shape.

The bottom surface of the buffer material 220a contacts the upper portion 114a of the main unit 113b, and the cone point of the buffer material 220a contacts the first pressure sensor 403a. Similarly, the bottom surface of the buffer material 220b contacts the bottom portion 114b of the main unit 113b, and the cone point of the buffer material 220b contacts the second pressure sensor 403b.

When the user presses the input member 113a in the direction of R1, the input device 213 rotates around the fulcrum 401 in the direction of R1. At this time, the upper portion 114a of the main unit 113b presses the bottom surface of the conical buffer material 220a, and then the cone point of the buffer material 220a presses the first pressure sensor 403a. When the user presses the input member 113a in the direction of R2, the input device 213 rotates around the fulcrum 401 in the direction of R2. At this time, the bottom portion 114b of the main unit 113b presses the bottom surface of the conical buffer material 220b, and then the cone point of the buffer material 220b presses the second pressure sensor 403b.

Because each of the conical buffer materials 220a and 220b contacts the main unit 113b at the bottom surface thereof, and contacts the pressure sensor at the cone point thereof, the contact point between the buffer materials 220a and 220b and the pressure sensors changes from a point to a larger circular area according to the increase of the pressure force. As a result, the changing operation force absorbed by the buffer materials 220a and 220b enables the control by the subtler force of the finger.

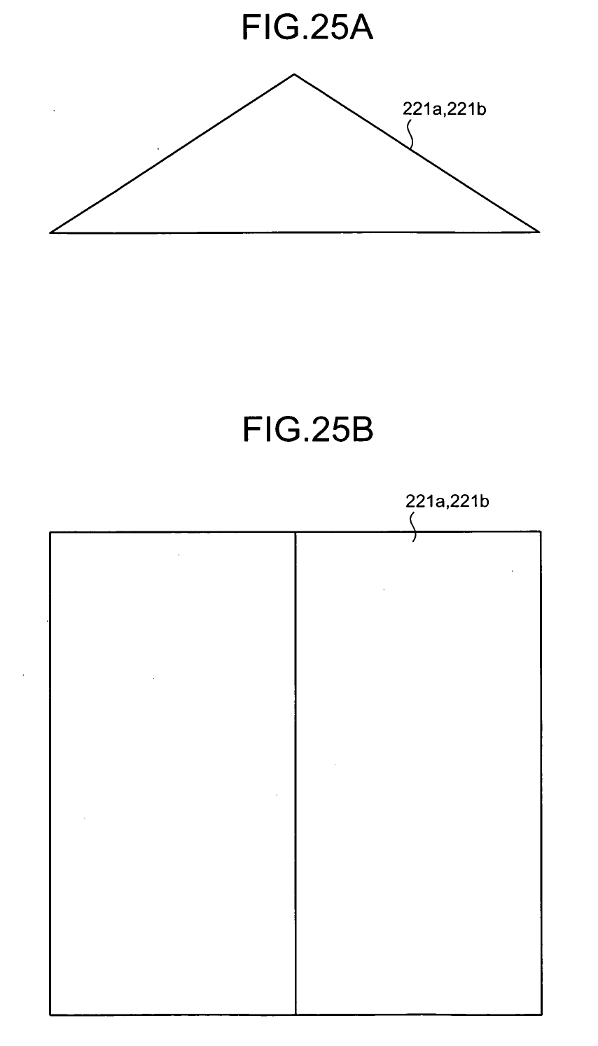

FIG. 25A is a cross section of buffer materials 221a and 221b according to a fifteenth embodiment; and FIG. 25B is a top view of the buffer materials 221a and 221b. An explanation is made while referencing FIG. 23 because the configuration of the input device according to the fifteenth embodiment is same as that of the input device 213.

The buffer material 221a is provided between the upper portion 114a of the main unit 113b and the first pressure sensor 403a to reduce the impact of the pressure force by absorbing it and deliver it to the first pressure sensor 403a. The buffer materials 221b is also provided between the bottom portion 114b of the main unit 113b and the second pressure sensor 403b to reduce the impact of the pressure force by absorbing it and deliver it to the second pressure sensor 403b. The buffer materials 220a and 220b have an isosceles-triangular cross section, and form a triangular prism.

As shown in FIG. 23, the first surface forming a base of the isosceles triangle of the buffer material 221a contacts the upper portion of the main unit 113b, and the top edge of the buffer material 221a at which two other surfaces (the second surface and the third surface) meet contacts the first pressure sensor 403a. Similarly, the first surface forming a base of the isosceles triangle of the buffer material 221a contacts the bottom portion of the main unit 113b, and the top edge of the buffer material 221a at which the second surface meets the third surface contacts the second pressure sensor 403b.

When the user presses the input member 113a in the direction of R1, the input device 213 rotates around the fulcrum 401 in the direction of R1. At this time, the upper portion 114a of the main unit 113b presses the first surface of the buffer material 221a, and then the top edge of the buffer material 221a presses the first pressure sensor 403a. When the user presses the input member 113a in the direction of R2, the input device 213 rotates around the fulcrum 401 in the direction of R2. At this time, the bottom portion 114b of the main unit 113b presses the first surface of the buffer material 221b, and then the top edge of the buffer material 221b presses the second pressure sensor 403b.

Because each of the buffer materials 221a and 221b contacts the main unit 113b at the first surface thereof, and contacts the pressure sensor at the top edge thereof, the contact area between the buffer materials 221a and 221b and the pressure sensors changes from a thin line to a larger rectangular area according to the increase of the pressure force. As a result, the changing operation force absorbed by the buffer materials 221a and 221b enables control by the subtler force of the finger.

While the input members according to the first to fifteenth embodiments is made of the soft material including a concave or convex surface, an input member according to a sixteenth embodiment of the present invention is made of the soft material including a plurality of hollow spaces therein.

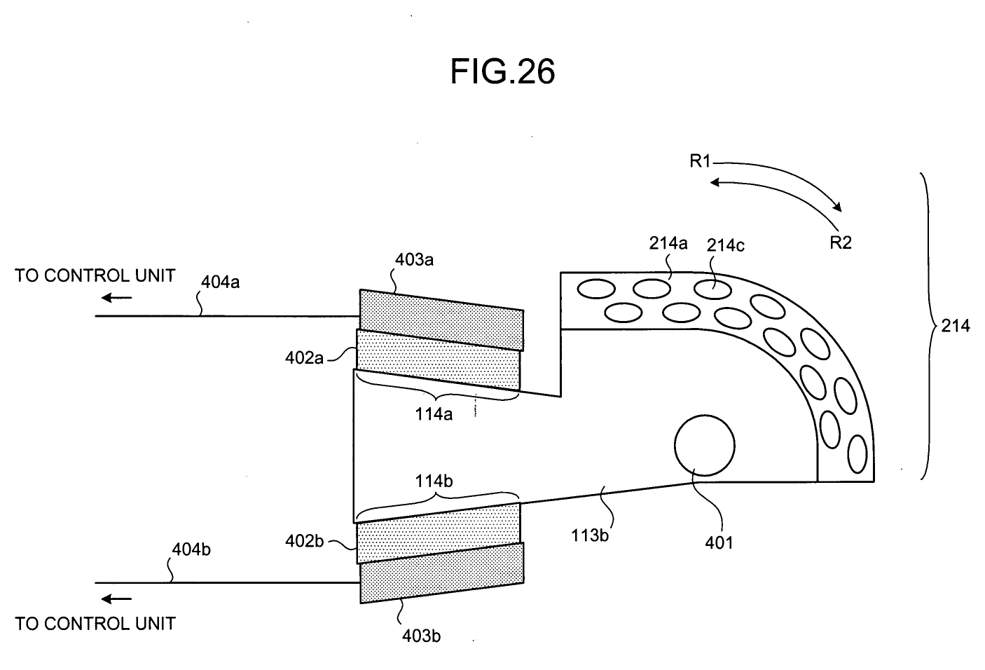

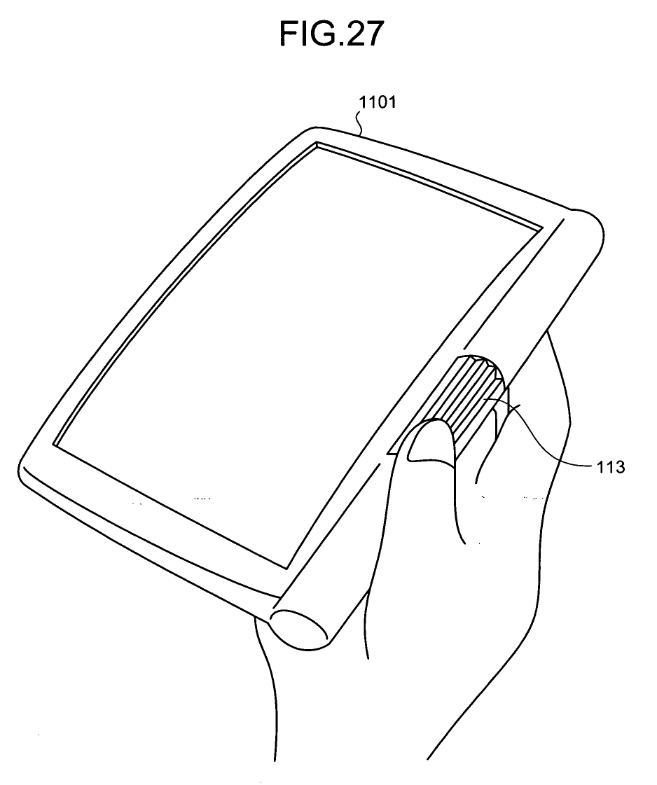

FIG. 26 is a cross section of an input device 214 according to the sixteenth embodiment.

A user presses an input member 214a with a finger and the like to input an instruction. The input member 214a is attached to the main unit 113b from the top of the step to the curved portion. The input member 214a includes a plurality of hollow spaces 214c by which the user can perform the input operation, and the input member 214a is made of a soft material such as silicone like the input member 113a according to the first embodiment.

When the user presses the input member 113a in the direction of R1 with a finger, the hollow spaces 214c are crushed to form a dent at which the finger is hooked, and the input device 213 rotates around the fulcrum 401 in the direction of R1. When the user presses the input member 113a in the direction of R2, the hollow spaces 214c are crushed to form the dent, and the input device 214 rotates around the fulcrum 401 in the direction of R2.

Because the input member 214a is made of the soft material including the hollow spaces 214c therein, a finger of the user hardly slips, and absorption of the pressure force realizes the control by the subtle force input from the finger with only one hand. Furthermore, the reduced operation force realizes the fine control and the input can be detected no matter it is intermittent or continuous. Because the input is performed by detecting the pressure force, the sliding action is not required and therefore wear of material can be prevented.

While the control devices according to the first to sixteenth embodiments are applied to the electronic paper, the control devices can be used to switch contents of data displayed on a mobile terminal such as a personal digital assistant (PDA). FIG. 27 is an example of the control device 100 according to any one of the first to sixteenth embodiments installed in the PDA. The input device 113 is integrated into the PDA chassis 1101.

In addition to switching contents of data displayed on the electronic paper or the PDA, the control device according to an aspect of the present invention can be applied to anything that requires a two-way control such as volume control in an audio player, flame control in a stove, and on/off control of lighting.

According to an aspect of the present invention, an accepting unit that is made of the soft material having at least one of a concave form and a convex form accepts an input from the user, and a detecting unit detects the operating force received by the accepting unit. As a result, a finger of the user hardly slips, and absorption of the pressure force realizes the control by the subtle force input from the finger with only one hand. It is also easy to recognize the input device at one view.

According to another aspect of the present invention, a delivering unit reduces the operating force received by the accepting unit and delivers the operating force to the detecting unit. As a result, the reduced operation force realizes the fine control and the input can be detected no matter it is intermittent or continuous. Because the input is performed by detecting the pressure force, the sliding action is not required and therefore wear of material can be prevented.

According to still another aspect of the present invention, the delivering unit includes a fulcrum and a main unit, and, when the user applies force to an effort point on the accepting unit, the main unit rotates around the fulcrum and applies the force to a load point near an end opposite to the accepting unit, whereby pressing the detecting unit. Because the input device presses the detecting unit based on the principle of leverage without rotating 360 degrees, the user can easily tell the start point and the end point of a single operation. Force of the input member 113a bouncing back from the pressure force to the finger also helps the user to know the start point and the end point of the single operation. Furthermore, because of the fulcrum of the leverage, absorption of the pressure force enables the control by the subtle pressure force.

According to still another aspect of the present invention, the accepting unit is made of the folded soft material including a plurality of protrusions over a surface of the main unit near the end thereof. Because the accepting unit is made of the folded soft material, the finger of the user hardly slips, and absorption of the pressure force realizes the control by the subtle force input from the finger with only one hand with only one hand. It is also easy to recognize the input device at one view. Furthermore, the reduced operation force realizes the fine control and the input can be detected no matter it is intermittent or continuous. Because the input is performed by detecting the pressure force, the sliding action is not required and therefore the wear of material can be prevented.

According to still another aspect of the present invention, because the accepting unit has a single protrusion and is made of the soft material provided over a surface of the main unit, a finger of the user hardly slips, and absorption of the pressure force realizes the control by the subtle force input from the finger with only one hand.

According to still another aspect of the present invention, because the accepting unit is made of the soft material protruding from the main unit, a finger of the user hardly slips, and absorption of the pressure force realizes the control by the subtle force input from the finger with only one hand.

According to still another aspect of the present invention, because the accepting unit is made of the soft material provided over a surface of the main unit and has a plurality of protrusions thereon, a finger of the user hardly slips, and absorption of the pressure force realizes the control by the subtle force input from the finger with only one hand.

According to still another aspect of the present invention, because the accepting unit is made of the soft material provided over a surface of the main unit and has two incurves forming a convex intersection thereon, a finger of the user hardly slips, and absorption of the pressure force realizes the control by the subtle force input from the finger with only one hand.

According to still another aspect of the present invention, because the accepting unit has a single dent and is made of the soft material provided over a surface of the main unit, a finger of the user hardly slips, and absorption of the pressure force realizes the control by the subtle force input from the finger with only one hand.

According to still another aspect of the present invention, because the accepting unit is made of the soft material provided over a surface of the main unit and has a plurality of folded protrusions in the concave portion thereon, a finger of the user hardly slips, and absorption of the pressure force realizes the control by the subtle force input from the finger with only one hand.

According to still another aspect of the present invention, because the accepting unit is made of the soft material provided over the surface of the main unit and has a plurality of cuts vertical to the surface, a finger of the user hardly slips, and absorption of the pressure force realizes the control by the subtle force input from the finger with only one hand.

According to still another aspect of the present invention, the accepting unit made of the soft material receives the operating force from the user, the detecting unit detects the operating force received by the accepting unit, and the delivering unit rotatable in two directions reduces the operating force received by the accepting unit and delivers the operating force to the detecting unit. As a result, a finger of the user hardly slips, and absorption of the pressure force realizes the control by the subtle force input from the finger with only one hand. The reduced operation force realizes the fine control and the input can be detected no matter it is intermittent or continuous. Because the input is performed by detecting the pressure force, the sliding action is not required and therefore wear of material can be prevented.

According to still another aspect of the present invention, the accepting unit is made of the soft material provided over the surface of the main unit, has a plurality of hollow spaces therein, and receives the operating force by the hollow spaces being crushed by the pressure force. As a result, a finger of the user hardly slips, and absorption of the pressure force realizes the control by the subtle force input from the finger with only one hand. The reduced operation force realizes the fine control and the input can be detected no matter it is intermittent or continuous. Because the input is performed by detecting the pressure force, the sliding action is not required and therefore wear of material can be prevented.

According to still another aspect of the present invention, because the fulcrum is configured to move between the effort point and the load point, the user can switch the position of the fulcrum, whereby the level of the force required for the input action can be adjusted.

According to still another aspect of the present invention, because the outer circumference of the fulcrum and the inner wall of the hole in the main unit are knurled to fit each other, the resistance produced by the contact between the fulcrum and the hole reduces the operating force enabling the control by subtle force of the finger.

According to still another aspect of the present invention, because the inner wall of the hole is made of the soft material, the resistance produced by the contact between the knurled outer circumference of the fulcrum and the inner wall of the hole reduces the operating force enabling the control by the subtler force of the finger.

According to still another aspect of the present invention, because the fulcrum includes a single protrusion and the main unit includes two protrusions that hold the single protrusion in between, the resistance produced by the contact between the single protrusion on the fulcrum and the protrusions in the main unit reduces the operating force enabling the control by the subtle force of the finger.

According to still another aspect of the present invention, because the outer circumference of the fulcrum is knurled and the inner wall of the hole has a single protrusion, the resistance produced by the contact between the knurled circumference and the protrusion in the main unit reduces the operating force enabling the control by the subtle force of the finger.

According to still another aspect of the present invention, buffer material provided between the main unit and the detecting unit reduces the impact of the pressure force from the main unit to the detecting unit. As a result, the operation force reduced by the buffer material enables the control by the subtle force of the finger.

According to still another aspect of the present invention, the buffer material has a tabular form, and the operation force reduced by the buffer material enables the control by the subtle force of the finger.

According to still another aspect of the present invention, a conical buffer material contacts the main unit at the bottom surface thereof, and contacts the detecting unit at the cone point thereof. When the pressure force increases, the contact point between the buffer material and the detecting unit changes from a point to a larger circular area, thus the changing operation force absorbed by the buffer material enables the control by the subtler force of the finger.

According to still another aspect of the present invention, a buffer material forming a triangular prism contacts the main unit at the first surface thereof, and contacts the detecting unit at the top edge thereof where the second surface meets the third surface. When the pressure force increases, the contact area between the buffer material and the pressure sensor changes from a thin line to a larger rectangular area, thus the changing operation force absorbed by the buffer material enables the control by the subtler force of the finger.

According to still another aspect of the present invention, a first pressure-detecting unit is disposed so that the first pressure-detecting unit is pressed by the load point on the main unit that rotates in the first direction when the user applies the force to the accepting unit in the first direction, and a second pressure-detecting unit is disposed so that the second pressure-detecting unit is pressed by the load point on the main unit that rotates in the second direction when the user applies the force to the accepting unit in the second direction. Because the detecting units are disposed in both directions, the input device can accept various inputs depending on the application.

According to still another aspect of the present invention, the accepting unit that is made of the soft material having at least one of the concave form and the convex form accepts an input from the user by receiving the operating force from the user, the detecting unit detects the operating force received by the accepting unit, and the control unit determines an operation to be performed based on the operating force detected by the detecting unit. As a result, a finger of the user hardly slips, and absorption of the pressure force realizes the control by the subtle force input from the finger with only one hand. It is also easy to recognize the input device at one view.

According to still another aspect of the present invention, the first pressure-detecting unit is disposed so that the first pressure-detecting unit is pressed by the load point on the main unit that rotates in the first direction when the user applies the force to the accepting unit in the first direction, and the second pressure-detecting unit is disposed so that the second pressure-detecting unit is pressed by the load point on the main unit that rotates in the second direction when the user applies the force to the accepting unit in the second direction. The control unit neutralizes the pressure force detected by the second pressure-detecting unit when the main unit rotates in the second direction in reaction to the pressure force to the first pressure-detecting unit, and the control unit neutralizes the pressure force detected by the first pressure-detecting unit when the main unit rotates in the first direction in reaction to the pressure force to the second pressure-detecting unit. Because the operation corresponding to each input action can be specified by determining which detecting unit is pressed, various operations can be specified. By neutralizing the pressure force as the reaction to the pressure force by any one of the detecting units when the pressure force is converted into electric signals, the noise can be reduced during the operation.

According to still another aspect of the present invention, the accepting unit made of the soft material receives the operating force from the user, the detecting unit detects the operating force received by the accepting unit, the delivering unit rotatable in two directions reduces the operating force received by the accepting unit and delivers the operating force to the detecting unit, and the control unit determines an operation to be performed based on the operating force detected by the detecting unit. As a result, a finger of the user hardly slips, and absorption of the pressure force realizes the control by the subtle force input from the finger with only one hand, whereby determining the operation.

According to still another aspect of the present invention, the storage unit stores data to be displayed on the display device, the display control unit provides control for displaying the data on the display device, the control unit determines how to display the data based on the pressure force detected by one of the pressure-detecting units, and the display control unit displays the data on the display device based on the operation determined by the control unit. As a result, the reduced pressure force realizes the fine control of displaying the data, and enables the input to be detected no matter it is intermittent or continuous.

According to still another aspect of the present invention, the control unit determines how to display the data based on the pressure force detected by the pressure-detecting unit. As a result, the reduced pressure force realizes the fine control of displaying the data based on the pressures force, and enables the input to be detected no matter it is intermittent or continuous.

According to still another aspect of the present invention, the control unit determines how to display the data based on the pressing time detected by the detecting unit. As a result, the reduced pressure force realizes the fine control of displaying the data based on the pressing time, and enables the input to be detected no matter it is intermittent or continuous.

According to still another aspect of the present invention, the control unit determines how to display the data based on the pressing speed detected by the detecting unit. As a result, the reduced pressure force realizes the fine control of displaying the data based on the pressing speed, and enables the input to be detected no matter it is intermittent or continuous.

According to still another aspect of the present invention, when the first pressure detecting unit detects the pressure force, the control unit advances the contents of the data displayed on the display unit. As a result, the reduced pressure force realizes the fine control of displaying the data to be advanced, and enables the input to be detected no matter it is intermittent or continuous.

According to still another aspect of the present invention, when the second pressure detecting unit detects the pressure force, the control unit rewinds the contents of the data displayed on the display unit. As a result, the reduced pressure force realizes the fine control of displaying the data to be rewound, and enables the input to be detected no matter it is intermittent or continuous.

According to still another aspect of the present invention, the accepting unit accepts the input by receiving the operating force from the user, the delivering unit reduces and delivers the operating force to the detecting unit, and the detecting unit detects the accepted operating force. Because the accepting unit is made of the soft elastic material, a finger of the user hardly slips, and absorption of the pressure force realizes the control by the subtle force input from the finger. Furthermore, the reduced operation force realizes the fine control and the input can be detected no matter it is intermittent or continuous. Because the input is performed by detecting the pressure force, the sliding action is not required and therefore wear of material can be prevented.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A control device comprising:
an accepting unit that is made of a soft material having at least one of a concave form and a convex form and accepts an input from a user by receiving operating force from the user;
a detecting unit that detects the operating force received by the accepting unit; and
a control unit that determines an operation to be performed based on the operating force detected by the detecting unit.

2. The control device according to claim 1, further comprising a delivering unit that reduces the operating force received by the accepting unit and delivers the operating force to the detecting unit.

3. The control device according to claim 2, wherein
the delivering unit includes a fulcrum closer to the accepting unit and a main unit supported by the fulcrum so as to rotate in two directions, and
when the user applies force to an effort point on the accepting unit, the main unit rotates around the fulcrum and applies the force to a load point near an end of the main unit opposite to the accepting unit, whereby pressing the detecting unit.

4. The control device according to claim 3, wherein
the detecting unit includes a first pressure-detecting unit and a second pressure-detecting unit that opposes the first pressure-detecting unit,
the first pressure-detecting unit is pressed by the load point on the main unit that rotates in a first direction when the user applies the force to the accepting unit in the first direction, and
the second pressure-detecting unit is pressed by the load point on the main unit that rotates in a second direction when the user applies the force to the accepting unit in the second direction.

5. The control device according to claim 4, wherein
the control unit neutralizes pressure force detected by the second pressure-detecting unit when the main unit rotates in the second direction in reaction to pressure force applied to the first pressure-detecting unit, and
the control unit neutralizes pressure force detected by the first pressure-detecting unit when the main unit rotates in the first direction in reaction to the pressure force applied to the second pressure-detecting unit.

6. The control device according to claim 1, further comprising:
a storage unit that stores data to be displayed on a predetermined display device; and
a display control unit that provides control for displaying the data on the predetermined display device, wherein
the control unit determines an operation of displaying the data based on the pressure force detected by the detecting unit, and
the display control unit displays the data on the predetermined display device based on the operation determined by the control unit.

7. A control device comprising:
an accepting unit that is made of a soft material and accepts an input from a user by receiving operating force from the user;
a detecting unit that detects the operating force received by the accepting unit;
a delivering unit that reduces the operating force received by the accepting unit and delivers the operating force to the detecting unit; and
a control unit that determines an operation to be performed based on the operating force detected by the detecting unit.

8. The control device according to claim 7, wherein
the delivering unit includes a fulcrum closer to the accepting unit and a main unit supported by the fulcrum so as to rotate in two directions, and
when the user applies force to an effort point on the accepting unit, the main unit rotates around the fulcrum and applies the force to a load point near an end of the main unit opposite to the accepting unit, whereby pressing the detecting unit.

9. The control device according to claim 8, wherein
the detecting unit includes a first pressure-detecting unit and a second pressure-detecting unit that opposes the first pressure-detecting unit,
the first pressure-detecting unit is pressed by the load point on the main unit that rotates in a first direction when the user applies the force to the accepting unit in the first direction, and
the second pressure-detecting unit is pressed by the load point on the main unit that rotates in a second direction when the user applies the force to the accepting unit in the second direction.

10. The control device according to claim 9, wherein
the control unit neutralizes pressure force detected by the second pressure-detecting unit when the main unit rotates in the second direction in reaction to pressure force applied to the first pressure-detecting unit, and
the control unit neutralizes pressure force detected by the first pressure-detecting unit when the main unit rotates in the first direction in reaction to the pressure force applied to the second pressure-detecting unit.

11. The control device according to claim 7, further comprising:
a storage unit that stores data to be displayed on a predetermined display device; and
a display control unit that provides control for displaying the data on the predetermined display device, wherein
the control unit determines an operation of displaying the data based on the pressure force detected by the detecting unit, and
the display control unit displays the data on the predetermined display device based on the operation determined by the control unit.

12. A controlling method comprising:
accepting an input from a user by receiving operating force from an accepting unit that is made of a soft material having at least one of a concave form and a convex form;
detecting the operating force received by the accepting unit using a detecting unit; and
determining an operation to be performed based on the operating force detected by the detecting unit.

13. The control device according to claim 12, further comprising absorbing the operating force received by the accepting unit and delivering the operating force to the detecting unit.

14. The controlling method according to claim 13, further comprising pressing the detecting unit by a main unit that rotates around a fulcrum in two directions.

15. The controlling method according to claim 14, further comprising:
neutralizing pressure force detected by a second pressure-detecting unit when the main unit rotates in a second direction in reaction to pressure force applied to a first pressure-detecting unit; and
neutralizing pressure force detected by the first pressure-detecting unit when the main unit rotates in a first direction in reaction to pressure force applied to the second pressure-detecting unit.

16. The controlling method according to claim 15, further comprising:
determining an operation of displaying data based on the pressure force detected by the detecting unit, and
displaying the data on a predetermined display device based on the operation determined at the determining.

17. A computer program product comprising a computer usable medium having computer readable program codes embodied in the medium that when executed causes a computer to execute:
determining an operation of displaying data based on at least one of a level of operating force received by an accepting unit that is made of a soft material having at least one of a concave form and a convex form, a duration time of the operating force, and a speed of the operating force; and
displaying the data based on the operation determined at the determining.
